(19) United States
(12) Patent Application Publication
(10) Pub. No.: US 2016/0047053 A1
(43) Pub. Date: Feb. 18, 2016

(54) ETCHING SOLUTION, ETCHING SOLUTION KIT, ETCHING METHOD USING SAME, AND METHOD FOR MANUFACTURING SEMICONDUCTOR SUBSTRATE PRODUCT

(71) Applicant: FUJIFILM Corporation, Tokyo (JP)

(72) Inventors: Yasuo SUGISHIMA, Haibara-gun (JP); Satomi TAKAHASHI, Haibara-gun (JP); Akiko KOYAMA, Haibara-gun (JP); Tetsuya KAMIMURA, Haibara-gun (JP)

(73) Assignee: FUJIFILM CORPORATION, Tokyo (JP)

(21) Appl. No.: 14/928,010

(22) Filed: Oct. 30, 2015

Related U.S. Application Data
(63) Continuation of application No. PCT/JP2014/062066, filed on May 1, 2014.

(30) Foreign Application Priority Data
May 2, 2013 (JP) 2013-097156

(51) Int. Cl. C23F 1/32; H01L 21/306

(52) U.S. Cl. CPC C23F 1/32; H01L 21/30604

(57) ABSTRACT

There is provided an etching solution of a semiconductor substrate that includes a first layer containing germanium (Ge) and a second layer containing a specific metal element other than germanium (Ge), the etching solution selectively removing the second layer and including an organic alkali compound.

### CROSS-REFERENCE TO RELATED APPLICATIONS

This application is a Continuation of PCT International Application No. PCT/JP2014/062066 filed on May 1, 2014, which claims priority under 35 U.S.C. §119 (a) to Japanese Patent Application No. 2013-097156 filed in Japan on May 2, 2013. Each of the above applications is hereby expressly incorporated by reference, in its entirety, into the present application.

### BACKGROUND OF THE INVENTION

1. Field of the Invention

The present invention relates to an etching solution, an etching solution kit, an etching method using the same, and a method for manufacturing a semiconductor substrate product.

2. Description of the Related Art

An integrated circuit is manufactured in multi-stages of various processing processes. Specifically, in the manufacturing process, deposition of various materials, lithography of a layer whose necessary portion or entire portion is exposed, or etching of the layer is repeated several times. Among these, the etching of a layer of a metal or a metal compound becomes to be an important process. A metal or the like is selectively etched and other layers are required to remain without corroding. In some cases, it is necessary that only a predetermined layer be removed in the form in which layers formed of similar metals and a layer with high corrosivity remain. A wiring in a semiconductor substrate or the size of an integrated circuit becomes smaller and thus the importance of performing etching on a member to accurately remain without corroding has been increasing.

When an example of a field effect transistor is considered, thinning of a silicide layer to be formed on the upper surface of a source and drain region and development of a new material have been strongly demanded along with rapid miniaturization of the field effect transistor. In a salicide process (salicide: self-aligned silicide) of forming the silicide layer, a part of a source region and a drain region formed of silicon and the like formed on a semiconductor substrate and a metal layer attached to the upper surface thereof are annealed. As a metal layer, tungsten (W), titanium (Ti), or cobalt (Co) is used, and more recently nickel (Ni) is being used. In this manner, a silicide layer with low resistance can be formed on the upper side of a source and drain electrode or the like. Currently, in response to further miniaturization, formation of a NiPt silicide layer to which platinum (Pt) which is a noble metal is added has been suggested.

After the salicide process is performed, the metal layer remaining in the region is removed by etching. The etching is normally performed through wet etching and a mixed solution (aqua regia) of hydrochloric acid and nitric acid is used as a liquid chemical. WO2012/125401A discloses an example of using a liquid chemical to which toluenesulfonic acid is added in addition to nitric acid and hydrochloric acid.

### SUMMARY OF THE INVENTION

An object of the present invention is to provide an etching solution and an etching solution kit which is capable of selectively removing a layer containing a specific metal with respect to a layer containing germanium, an etching method using the same, and a method for manufacturing a semiconductor substrate product.

Acidic aqua regia is used for this kind of etching solution included in WO2012/125401A described above. In this case, the present inventors examined application of an alkaline etching solution. As a result, it is confirmed that the etching solution shows excellent resistance to damage with respect to germanium as shown in Examples below and a metal layer such as titanium or copper is suitably removed. The present invention is completed based on such knowledge.

The above-described problems are solved by the following means.

[1] An etching solution of a semiconductor substrate that includes a first layer containing germanium (Ge) and a second layer containing a specific metal element other than germanium (Ge), the etching solution selectively removing the second layer and including an organic alkali compound.

[2] The etching solution according to [1], in which the organic alkali compound is (a) a hydrocarbon amine compound having 3 or more carbon atoms, (b) an amine compound containing an oxygen atom or a sulfur atom, or (c) an ammonium compound having 5 or more carbon atoms or an ammonium compound having an oxygen atom or a sulfur atom.

[3] The etching solution according to [1] or [2], in which the concentration of germanium (Ge) of the first layer is 40% by mass or greater.

[4] The etching solution according to any one of [1] to [3], in which the specific metal element constituting the second layer is selected from nickel platinum (NiPt), titanium (Ti), nickel (Ni), and cobalt (Co).

[5] The etching solution according to any one of [1] to [4], in which the organic alkali compound is a compound represented by any of the following Formulae (O-1) to (O-3), (P-1) to (P-3), and (Q-1), a compound having a repeating unit selected from the following Formulae (a-1) to (a-8), or a compound represented by the following Formula (b).

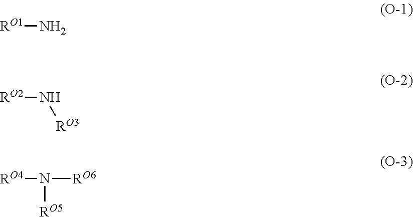

In the formulae, R⁰¹ each independently represents an alkyl group (having 3 to 12 carbon atoms), an alkenyl group (having 1 to 12 carbon atoms), an alkynyl group (having 1 to 12 carbon atoms), or an aryl group (having 6 to 14 carbon atoms). R⁰² to R⁰⁶ each independently represent an alkyl group (having 1 to 12 carbon atoms), an alkenyl group (having 1 to 12 carbon atoms), an alkynyl group (having 1 to 12 carbon atoms), or an aryl group (having 6 to 14 carbon atoms). In this case, the alkyl group, the alkenyl group, the alkynyl group, or the aryl group herein may further include an amino group, but do not include a substituent having an oxygen atom or a sulfur atom.

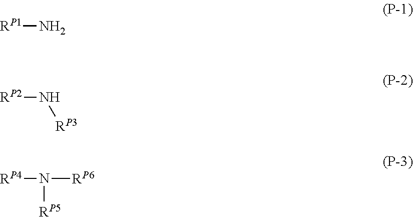

In the formulae, R^{P1} to R^{P6} each independently represent an acyl group (having 1 to 6 carbon atoms), an alkoxy group (having 1 to 6 carbon atoms), an alkoxycarbonyl group (having 2 to 6 carbon atoms), an alkoxycarbonylamino group (having 2 to 6 carbon atoms), a group represented by the following Formula (x), an alkyl group (having 1 to 6 carbon atoms), an alkynyl group (having 2 to 6 carbon atoms), an alkenyl group (having 2 to 6 carbon atoms), an aryl group (having 6 to 10 carbon atoms), or a heterocyclic group (having 2 to 6 carbon atoms). In this case, R^{P1} in Formula (P-1) does not only represent a hydrocarbon group. Both of R^{P2} and R^{P3} in Formula (P-2) do not represent a hydrocarbon group. In Formula (P-3), all of R^{P4} to R^{P6} do not only represent a hydrocarbon group.

X1-(Rx1-X2)mx-Rx2-* (X)

X1 represents a hydroxy group, a sulfanyl group, an alkoxy group having 1 to 4 carbon atoms, or a thioalkoxy group having 1 to 4 carbon atoms. Rx1 and Rx2 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these. X2 represents O, S, CO, NR^{N} (R^{N} represents a hydrogen atom or an alkyl group having 1 to 6 carbon atoms). mx represents an integer of 0 to 6. When mx is 2 or greater, a plurality of Rx1's and X2's may be different from each other. Rx1 and Rx2 may further include a substituent T. The symbol indicates an atomic bond.

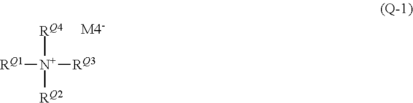

In the formula, R^{Q1} to R^{Q4} each independently represent an alkyl group having 1 to 20 carbon atoms, an alkenyl group having 2 to 20 carbon atoms, an alkynyl group having 2 to 20 carbon atoms, an aryl group having 6 to 14 carbon atoms, an aralkyl group having 7 to 14 carbon atoms, or a group represented by the following Formula (y). In this case, when the total number of carbon atoms of R^{Q1} to R^{Q4} is 5 or more or the total number of carbon atoms of R^{Q1} to R^{Q4} is 4, any one of R^{Q1} to R^{Q4} includes a substituent having an oxygen atom or a sulfur atom.

Y1-(Ry1-Y2)my-Ry2-* (y)

Y1 represents an alkyl group having 1 to 12 carbon atoms, an alkenyl group having 2 to 12 carbon atoms, an alkynyl group having 2 to 12 carbon atoms, an aralkyl group having 7 to 14 carbon atoms, an aryl group having 6 to 14 carbon atoms, a hydroxy group, a sulfanyl group, an alkoxy group having 1 to 4 carbon atoms, or a thioalkoxy group having 1 to 4 carbon atoms. Y2 represents O, S, CO, or NR^{N} (R^{N} represents a hydrogen atom or an alkyl group having 1 to 6 carbon atoms). Ry1 and Ry2 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these. my represents an integer of 0 to 6. When my is 2 or greater, a plurality of Ry1's and Y2's may be different from each other. Ry1 and Ry2 may further include a substituent T. The symbol “*” indicates an atomic bond.

M4⁻ represents a counterion.

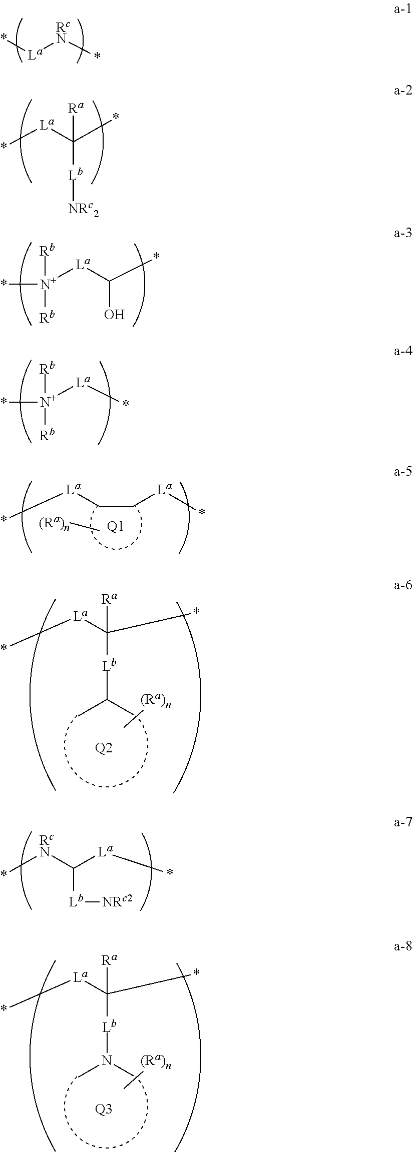

R^{a} represents a hydrogen atom, an alkyl group, an alkenyl group, an aryl group, or a heterocyclic group. R^{b} represents an alkyl group or an alkenyl group. L^{a} represents an alkylene group, a carbonyl group, an imino group, an arylene group, a heterocyclic group, or a combination of these. Among these, an alkylene group or a carbonyl group is preferable. L^{b} represents a single bond, an alkylene group, a carbonyl group, an imino group, an arylene group, a heterocyclic group, or a combination of these. R^{c} represents a hydrogen atom or an alkyl group. n represents an integer of 0 or greater. Q1 to Q3 each independently represent a nitrogen-containing heterocycle.

R^{c}₂N-[L^{d}-N(R^{c})]ₘ-L^{d}-NR^{c}₂ (b)

R^{c} represents a hydrogen atom or an alkyl group. m represents an integer of 0 or greater. L^{d} represents an alkylene group, a carbonyl group, an imino group, an arylene group, a heterocyclic group, or a combination of these.

[6] The etching solution according to any one of [1] to [5], in which the organic alkali compound is selected from a group consisting of an alkylamine compound having 3 or more carbon atoms, an alkylammonium compound having 5 or more carbon atoms, a carbamoyl compound, and an alkoxyamine compound.

[7] The etching solution according to any one of [1] to [6], in which the content of the organic alkali compound is in the range of 3% by mass to 100% by mass.

[8] The etching solution according to any one of [1] to [7], in which the second layer is selectively removed with respect to the first layer and the following third layer.

Third layer: layer containing germanium (Ge) and the specific metal element, which is interposed between the first layer and the second layer

[9] The etching solution according to any one of [1] to [8], further containing the following organic additive.

Organic additive: an additive formed of an organic compound which contains a nitrogen atom, a sulfur atom, a phosphorous atom, or an oxygen atom

[10] An etching solution kit of a semiconductor substrate that includes a first layer containing germanium (Ge) and a second layer containing a metal element, the kit selectively removing the second layer including: a first liquid which contains organic alkali compound; and a second liquid which contains an oxidant.

[11] An etching method of a semiconductor substrate that includes a first layer containing germanium (Ge) and a second layer containing a specific metal element other than germanium (Ge), the method including: selectively removing the second layer and using an etching solution containing an organic alkali compound is used.

[12] The etching method according to [11], in which the organic alkali compound is (a) a hydrocarbon amine compound having 5 or more carbon atoms, (b) an amine compound containing a heteroatom, or (c) an ammonium compound.

[13] The etching method according to [11] or [12], in which the concentration of germanium (Ge) of the first layer is 40% by mass or greater.

[14] The etching method according to any one of [11] to [13], in which the specific metal element constituting the second layer is selected from nickel platinum (NiPt), titanium (Ti), nickel (Ni), and cobalt (Co).

[15] The etching method according to any one of [11] to [14], in which the organic alkali compound is a compound represented by any of the following Formulae (O-1) to (O-3), (P-1) to (P-3), and (Q−1), a compound having a repeating unit selected from the following Formulae (a-1) to (a-8), or a compound represented by the following Formula (b).

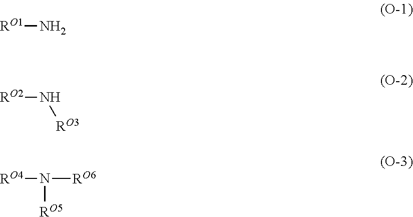

In the formulae, R⁰¹ each independently represents an alkyl group (having 3 to 12 carbon atoms), an alkenyl group (having 1 to 12 carbon atoms), an alkynyl group (having 1 to 12 carbon atoms), or an aryl group (having 6 to 14 carbon atoms). R⁰² to R⁰⁶ each independently represent an alkyl group (having 1 to 12 carbon atoms), an alkenyl group (having 1 to 12 carbon atoms), an alkynyl group (having 1 to 12 carbon atoms), or an aryl group (having 6 to 14 carbon atoms). In this case, the alkyl group, the alkenyl group, the alkynyl group, or the aryl group herein may further include an amino group, but do not include a substituent having an oxygen atom or a sulfur atom.

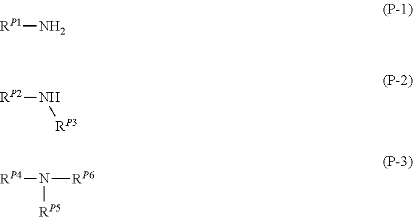

In the formulae, R^{P1} to R^{P6} each independently represent an acyl group (having 1 to 6 carbon atoms), an alkoxy group (having 1 to 6 carbon atoms), an alkoxycarbonyl group (having 2 to 6 carbon atoms), an alkoxycarbonylamino group (having 2 to 6 carbon atoms), a group represented by the following Formula (x), an alkyl group (having 1 to 6 carbon atoms), an alkynyl group (having 2 to 6 carbon atoms), an alkenyl group (having 2 to 6 carbon atoms), an aryl group (having 6 to 10 carbon atoms), or a heterocyclic group (having 2 to 6 carbon atoms). In this case, R^{P1} in Formula (P-1) does not represent a hydrocarbon group. Both of R^{P}2 and R^{P3} in Formula (P-2) do not only represent a hydrocarbon group. In Formula (P-3), all of R^{P4} to R^{P6} do not only represent a hydrocarbon group.

X1-(Rx1-X2)mx-Rx2-* (X)

X1 represents a hydroxy group, a sulfanyl group, an alkoxy group having 1 to 4 carbon atoms, or a thioalkoxy group having 1 to 4 carbon atoms. Rx1 and Rx2 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these. X2 represents O, S, CO, NR^{N} (R^{N} represents a hydrogen atom or an alkyl group having 1 to 6 carbon atoms). mx represents an integer of 0 to 6. When mx is 2 or greater, a plurality of Rx1's and X2's may be different from each other. Rx1 and Rx2 may further include a substituent T. The symbol “*” indicates an atomic bond.

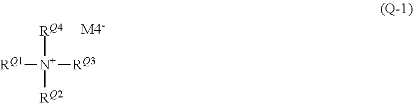

In the formula, R^{Q1} to R^{Q4} each independently represent an alkyl group having 1 to 20 carbon atoms, an alkenyl group having 2 to 20 carbon atoms, an alkynyl group having 2 to 20 carbon atoms, an aryl group having 6 to 14 carbon atoms, an aralkyl group having 7 to 14 carbon atoms, or a group represented by the following Formula (y). In this case, when the total number of carbon atoms of R^{Q1} to R^{Q4} is 5 or more or the total number of carbon atoms of R^{Q1} to R^{Q4} is 4, any one of R^{Q1} to R^{Q4} includes a substituent having an oxygen atom or a sulfur atom.

Y1-(Ry1-Y2)my-Ry2-* (y)

Y1 represents an alkyl group having 1 to 12 carbon atoms, an alkenyl group having 2 to 12 carbon atoms, an alkynyl group having 2 to 12 carbon atoms, an aralkyl group having 7 to 14 carbon atoms, an aryl group having 6 to 14 carbon atoms, a hydroxy group, a sulfanyl group, an alkoxy group having 1 to 4 carbon atoms, or a thioalkoxy group having 1 to 4 carbon atoms. Y2 represents O, S, CO, or NR^{N} (R^{N} represents a hydrogen atom or an alkyl group having 1 to 6 carbon atoms). Ry1 and Ry2 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these. my represents an integer of 0 to 6. When my is 2 or greater, a plurality of Ry1's and Y2's may be different from each other. Ry1 and Ry2 may further include a substituent T. The symbol “*” indicates an atomic bond.

M4⁻ represents a counterion.

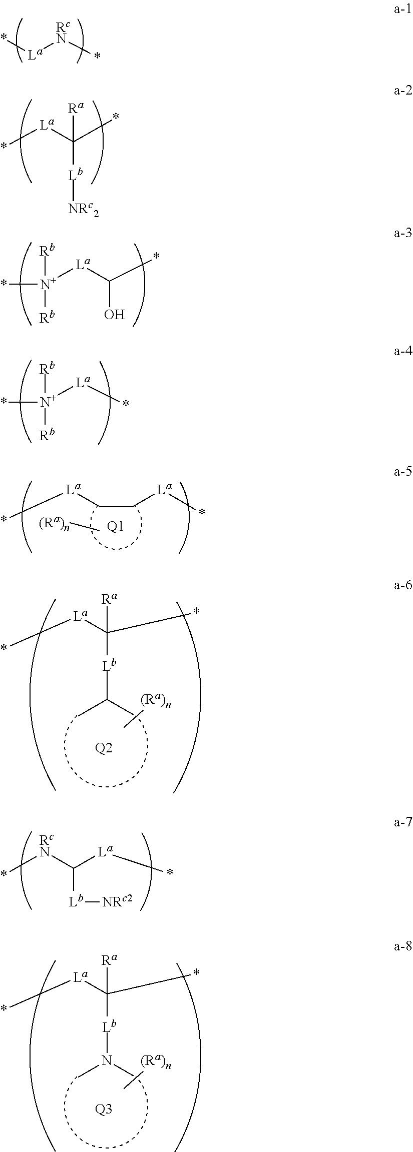

R^{a} represents a hydrogen atom, an alkyl group, an alkenyl group, an aryl group, or a heterocyclic group. R^{b} represents an alkyl group or an alkenyl group. L^{a} represents an alkylene group, a carbonyl group, an imino group, an arylene group, a heterocyclic group, or a combination of these. Among these, an alkylene group or a carbonyl group is preferable. L^{b} represents a single bond, an alkylene group, a carbonyl group, an imino group, an arylene group, a heterocyclic group, or a combination of these. R^{c} represents a hydrogen atom or an alkyl group. n represents an integer of 0 or greater. Q1 to Q3 each independently represent a nitrogen-containing heterocycle.

R^{c}₂N-[L^{d}-N(R^{c})]ₘ-L^{d}-NR^{c}₂ (b)

R^{c} represents a hydrogen atom or an alkyl group. m represents an integer of 0 or greater. L^{d} represents an alkylene group, a carbonyl group, an imino group, an arylene group, a heterocyclic group, or a combination of these.

[16] The etching method according to any one of [11] to [15], in which the content of the organic alkali compound is in the range of 3% by mass to 100% by mass.

[17] The etching method according to any one of [11] to [16], in which the second layer is selectively removed with respect to the first layer and the following third layer.

Third layer: layer containing germanium (Ge) and the specific metal element, which is interposed between the first layer and the second layer

[18] The etching method according to any one of [11] to [17], further including: allowing the semiconductor substrate to rotate and supplying the etching solution through a nozzle from the upper surface of the semiconductor substrate during rotation when the etching solution is provided for the semiconductor substrate.

[19] The etching method according to any one of [11] to [18], in which the temperature of the etching solution at the time of being brought into contact with the second layer is in the range of 30° C. to 80° C.

[20] The etching method according to any one of [11] to [19], further including: a process of washing the semiconductor substrate with water at least before or after the etching.

[21] The etching method according to any one of [11] to [20], in which the etching solution further contains an oxidant, and a first liquid which does not contain the oxidant and a second liquid which contains the oxidant are separated from each other and then stored.

[22] A method for manufacturing a semiconductor substrate product that includes a first layer containing germanium (Ge), including: a step of forming at least the first layer and at least one second layer selected from nickel platinum (NiPt), titanium (Ti), nickel (Ni), and cobalt (Co) on the semiconductor substrate; a step of forming a third layer containing components of the first layer and the second layer between both layers by heating the semiconductor substrate; a step of preparing an etching solution containing an organic alkali compound; and a step of bringing the etching solution into contact with the second layer and selectively removing the second layer with respect to the first layer and/or the third layer.

According to the etching solution and the etching solution kit, the etching method using the same, and the method for manufacturing a semiconductor substrate product of the present invention, a layer containing a specific metal can be selectively removed with respect to a layer containing germanium.

The above-described features, other features, and advantages of the present invention will become more apparent from the following description and the accompanying drawings.

### BRIEF DESCRIPTION OF THE DRAWINGS

FIG. 1(a), FIG. 1(b), and FIG. 1(c) each are a sectional view schematically illustrating examples of a process of preparing a semiconductor substrate according to an embodiment of the present invention.

FIG. 2(A), FIG. 2(B), FIG. 2(C), FIG. 2(D) and FIG. 2(E) each are a process view illustrating examples of manufacturing a MOS transistor according to an embodiment of the present invention.

FIG. 3 is a configuration view of a device illustrating a part of a wet etching device according to a preferred embodiment of the present invention.

FIG. 4 is a plan view schematically illustrating a movement trajectory line of a nozzle with respect to a semiconductor substrate according to an embodiment of the present invention.

FIG. 5 is a sectional view schematically illustrating a structure of a substrate according to another embodiment of the present invention.

### DESCRIPTION OF THE PREFERRED EMBODIMENTS

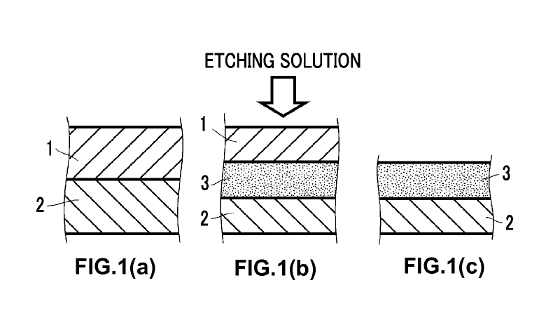

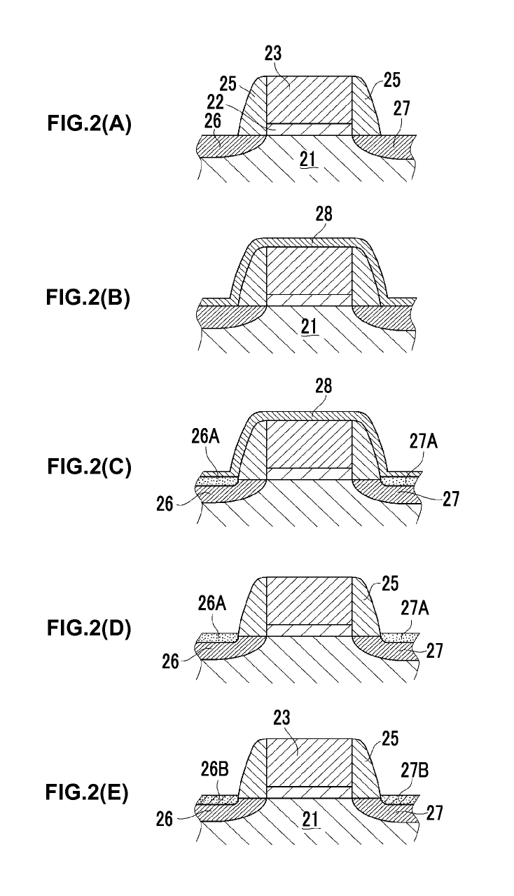

First, preferred embodiments of an etching process according to an etching method for the present invention will be described with reference to FIGS. 1 and 2.

[Etching Process]

FIG. 1(a), FIG. 1(b), and FIG. 1(c) each are a view illustrating a semiconductor substrate before and after etching is performed. In preparation examples of the present embodiment, a metal layer (second layer) 1 is arranged on the upper surface of a silicon layer (first layer) 2. As the silicon layer (first layer), a SiGe epitaxial layer constituting a source electrode or a drain electrode is used. In the present invention, it is preferable that the silicon layer is a SiGe epitaxial layer in such terms that remarkable effects of the etching solution are exhibited.

As a constituent material of the metal layer (second layer) 1, tungsten (W), titanium (Ti), cobalt (Co), nickel (Ni), or nickel platinum (NiPt) is exemplified. In order to form a metal layer, a method normally used for forming such a metal layer can be used. Specifically, a film formation method using chemical vapor deposition (CVD) is exemplified. In this case, the thickness of the metal layer is not particularly limited, but a film whose thickness is in the range of 5 nm to 50 nm is exemplified. In the present invention, it is preferable that a metal layer is a NiPt layer (the content of Pt is preferably in the range of more than 0% by mass to 20% by mass) or a Ni layer (the content of Pt is 0% by mass) in terms such that remarkable effects of the etching liquid are exhibited.

The metal layer may contain other elements other than the metal elements exemplified above. For example, oxygen or nitrogen which is inevitably mixed thereinto may be present. It is preferable that the amount of inevitable impurities is suppressed within the range of 1 ppt to 10 ppm, for example. From such a viewpoint, it is preferable that the second layer (metal layer) is a layer substantially formed of metal elements. For example, in a case of Ti, a TiN layer or the like is not included and it is preferable that the second layer is a metal layer of titanium (Ti).

Further, materials which are not desired to be etched are present on the semiconductor substrate in addition to the materials described above. It is possible for the etching solution of the present invention to minimize corrosion of the materials which are not desired to be etched. As the materials which are not desired to be etched, at least one selected from a group consisting of Al, SiO₂, SiN, SiOC, HfO, and TiAlC is exemplified.

After the metal layer 1 is formed on the upper side of the silicon layer 2 in the above-described process (a), annealing (sintering) is performed and a metal-Si reaction film (third layer: germanium silicide layer) 3 is formed on the interface thereof (process (b)). The annealing may be performed under conditions normally used for manufacturing this kind of element, and a treatment performed in a temperature range of 200° C. to 1000° C. is exemplified. In this case, the thickness of the germanium silicide layer 3 is not particularly limited, but a layer whose thickness is 50 nm or less or a layer whose thickness is 10 nm or less is exemplified. The lower limit is not particularly limited, but the lower limit is substantially 1 nm or greater. The germanium silicide layer is used as a low resistance film and functions as a conductive portion that electrically connects a source electrode, a drain electrode positioned in the lower portion thereof and a wiring arranged in the upper portion thereof. Accordingly, conduction is inhibited when defects or corrosion occurs in the germanium silicide layer and this leads to degradation in quality such as malfunction of an element in some cases. Particularly, the structure of an integrated circuit in the inside of a substrate has been miniaturized and thus even a small amount of damage may have a great impact on the performance of the element. Consequently, it is desired to prevent such defects or corrosion as much as possible.

Moreover, in the present specification, the germanium silicide layer is included in the germanium-containing layer of the first layer in a broad sense. Therefore, selective removal of the second layer with respect to the first layer includes an aspect of preferentially removing the second layer (metal layer) with respect to the germanium-containing layer which is not silicided and an aspect of preferentially removing the second layer (metal layer) with respect to the germanium silicide layer. In a narrow sense, when it is necessary to distinguish the germanium-containing layer (excluding the germanium silicide layer) of the first layer from the germanium silicide layer of the third layer, the layers are respectively referred to as the first layer and the third layer.

Next, the remaining metal layer 1 is etched (process (b)→process (c)). In the present embodiment, the etching solution is used at this time and the metal layer 1 is removed by providing the etching solution from the upper side of the metal layer 1 to be in contact with the metal layer 1. The provision of the etching solution will be described below.

The silicon layer 2 is formed of a SiGe epitaxial layer and can be formed through crystal-growth on a silicon substrate having a specific crystallinity according to a chemical vapor deposition (CVD) method. Alternatively, an epitaxial layer formed from a desired crystallinity may be formed according to electron beam epitaxy (MBE).

In order to use the silicon layer as a P type layer, it is preferable that boron (B) whose concentration is in the range of 1×10¹⁴ cm⁻³ to 1×10²¹ cm⁻³ is doped. In order to use the germanium-containing layer as an N type layer, it is preferable that phosphorus (P) whose concentration is in the range of 1×10¹⁴ cm⁻³ to 1×10²¹ cm⁻³ is doped.

The Ge concentration in the SiGe epitaxial layer is preferably in the range of 20% by mass to 100% by mass and more preferably in the range of 40% by mass to 90% by mass. Since the in-plane uniformity of a treated wafer can be improved, it is preferable that the Ge concentration is set to be within the above-described range. The reason why it is preferable that Ge has a relatively high concentration is assumed as follows. In a case where Ge is compared with Si, it is understood that an oxide film SiOx is generated after Si is oxidized and the oxides become a reaction-stop layer without being eluted. For this reason, a difference is generated between a portion in which Ge is eluted and a portion in which the reaction is stopped due to SiOx within the wafer and thus the in-plane uniformity of the wafer is damaged. Meanwhile, it is considered that the influence of inhibition of SiOx according to the above-described mechanism becomes decreased when the Ge concentration becomes greater and thus the in-plane uniformity of the wafer can be secured when a liquid chemical with high removability with respect to the metal layer such as the etching solution of the present invention is used. In addition, in a case where the concentration of germanium is 100% by mass, a layer formed along with an alloy of the second layer resulting from the annealing contains germanium and specific metal elements of the second layer and does not contain silicon, but is referred to as germanium silicide layer including the above-described meaning for the sake of convenience in the present specification.

The germanium silicide layer (third layer) is a layer containing germanium (Ge) and the specific metal elements interposed between the first layer and the second layer. The composition thereof is not particularly limited, but “x+y” is preferably in the range of 0.2 to 0.8 and more preferably in the range of 0.3 to 0.7 in the formula of SixGeyMz (M: metal element) when “x+y+z” is set to 1. In a case of z, z is preferably in the range of 0.2 to 0.8 and more preferably in the range of 0.3 to 0.7. The preferable range of the ratio of x to y is as defined as the above. In this case, the third layer may contain other elements. This point is the same as that described in the section of the metal layer (second layer).

(Processing of MOS Transistor)

FIG. 2(A), FIG. 2(B), FIG. 2(C), FIG. 2(D) and FIG. 2(E) each are a process view illustrating examples of manufacturing a MOS transistor. FIG. 2(A) illustrates a process of forming the structure of the MOS transistor, FIG. 2(B) illustrates a process of sputtering the metal layer, FIG. 2(C) illustrates a first annealing process, FIG. 2(D) illustrates a process of selectively removing the metal layer, and FIG. 2(E) illustrates a second annealing process.

As illustrated in the figures, a gate electrode 23 is formed through a gate insulating film 22 formed on the surface of a silicon substrate 21. Extension regions may be individually formed on both sides of the gate electrode 23 of the silicon substrate 21. A protective layer (not illustrated) that prevents contact with a NiPt layer may be formed on the upper side of the gate electrode 23. Moreover, a side wall 25 formed of a silicon oxide film or a silicon nitride film is formed and a source electrode 26 and a drain electrode 27 are formed by ion implantation.

Next, as illustrated in the figures, a NiPt film 28 is formed and a rapid annealing treatment is performed. In this manner, elements in the NiPt film 28 are allowed to be diffused into the silicon substrate for silicidation (in the present specification, for the sake of convenience, an alloy resulting from annealing is referred to as silicidation including the case where the concentration of germanium is 100% by mass). As a result, the upper portion of the source electrode 26 and the drain electrode 27 is silicided and a NiPtGeSi source electrode portion 26A and a NiPtSiGe drain electrode portion 27A are formed. At this time, as illustrated in FIG. 2(E), an electrode member can be changed to be in a desired state by performing the second annealing if necessary. The temperature of the first annealing or the second annealing is not particularly limited, but the annealing can be performed in a temperature range of, for example, 400° C. to 1100° C.

The NiPt film 28 remaining without contributing to silicidation can be removed using the etching solution of the present invention (FIGS. 2(C) and 2(D)). At this time, illustration is made in a greatly schematic manner and the NiPt film remaining by being deposited on the upper portion of the silicided layer (26A and 27A) may or may not be present. The semiconductor substrate or the structure of the product is illustrated in a simplified manner and, if necessary, the illustration may be interpreted such that there is a required member.
Silicon substrate 21: Si, SiGe, and Ge
Gate insulating film 22: HfO₂ (High-k)
Gate electrode 23: Al, W, TiN, or Ta
Side wall 25: SiOCN, SiN, SiO₂ (low-k)
Source electrode 26: SiGe and Ge
Drain electrode 27: SiGe and Ge
Metal layer 28: Ni, Pt, and Ti
Cap (not illustrated): TiN

The semiconductor substrate to which the etching method for the present invention is applied is described above, but the etching method for the present invention can be applied to other semiconductor substrates without being limited to the specific example. For example, a semiconductor substrate including a high dielectric film or a metal gate FinFET which has a silicide pattern on the source region and/or the drain region is exemplified.

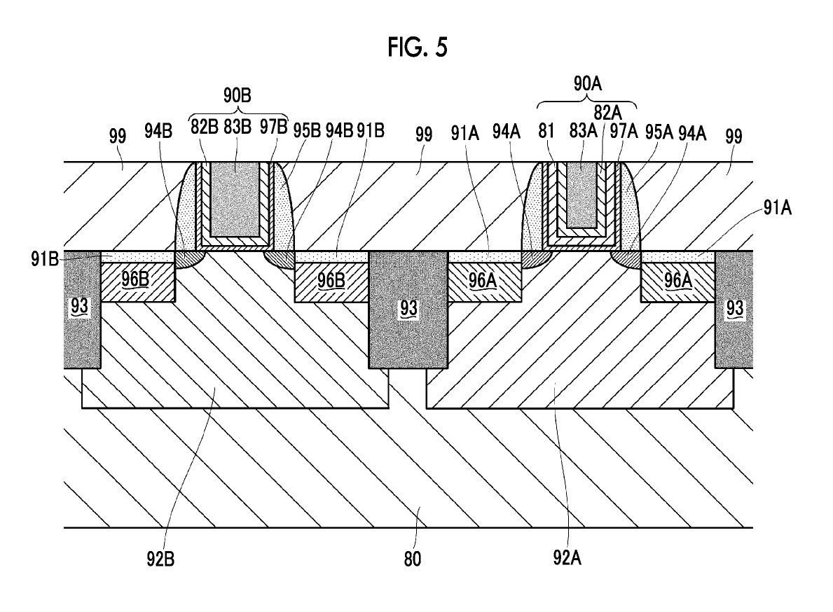

FIG. 5 is a sectional view schematically illustrating a structure of a substrate according to another embodiment of the present invention. The reference numeral 90A indicates a first gate stack positioned in a first device region. The reference numeral 90B indicates a second gate stack positioned in a second element region. Here, the gate stack contains a conductive tantalum alloy layer or TiAlC. When the first gate stack is described, the reference numeral 92A indicates a well. The reference numeral 94A indicates a first source/drain extension region, the reference numeral 96A indicates a first source/drain region, and the reference numeral 91A indicates a first metal semiconductor alloy portion. The reference numeral 95A indicates a first gate spacer. The reference numeral 97A indicates a first gate insulating film, the reference numeral 81 indicates a first work function material layer, and the reference numeral 82A indicates a second work function material layer. The reference numeral 83A indicates a first metal portion which becomes an electrode. The reference numeral 93 indicates a trench structure portion and the reference numeral 99 indicates a flattened dielectric layer. The reference numeral 80 indicates a lower semiconductor layer.

The first gate stack has the same structure as that of the second gate stack and the reference numerals 91B, 92B, 94B, 95B, 96B, 97B, 82B, and 83B respectively correspond to the reference numerals 91A, 92A, 94A, 95A, 96A, 97A, 82A, and 83A of the first gate stack. When a difference between both structures is described, the first gate stack includes the first work function material layer 81, but the second gate stack is not provided with such a layer.

The work function material layer may be any one of a p type work function material layer or an n type work function material layer. The p type work function material indicates a material having a work function between a valence band energy level and a mid-band gap energy level of silicon. That is, the energy level of a conduction band and the valence band energy level are equivalently separated from each other in the energy level of silicon. The n type work function material indicates a material having a work function between the energy level of the conduction band of silicon and the mid-band gap energy level of silicon.

It is preferable that the material of the work function material layer is a conductive tantalum alloy layer or TiAlC. The conductive tantalum alloy layer can contain a material selected from (i) an alloy of tantalum and aluminum, (ii) an alloy of tantalum and carbon, and (iii) an alloy of tantalum, aluminum, and carbon.

(i) TaAl

In the alloy of tantalum and aluminum, the atom concentration of tantalum can be set to be in the range of 10% to 99%. The atom concentration of aluminum can be set to be in the range of 1% to 90%.

(ii) TaC

In the alloy of tantalum and carbon, the atom concentration of tantalum can be set to be in the range of 20% to 80%. The atom concentration of carbon can be set to be in the range of 20% to 80%.

(iii) TaAlC

In the alloy of tantalum, aluminum, and carbon, the atom concentration of tantalum can be set to be in the range of 15% to 80%. The atom concentration of aluminum can be set to be in the range of 1% to 60%. The atom concentration of carbon can be set to be in the range of 15% to 80%.

In another embodiment, the work function material layer can be set to be (iv) a titanium nitride layer substantively formed of titanium nitride or (v) a layer of an alloy of titanium, aluminum, and carbon.

(iv) TiN

In the titanium nitride layer, the atom concentration of titanium can be set to be in the range of 30% to 90%. The atom concentration of nitrogen can be set to be in the range of 10% to 70%.

(v) TiAlC

In the layer of the alloy of titanium, aluminum, and carbon, the atom concentration of titanium can be set to be in the range of 15% to 45%. The atom concentration of aluminum can be set to be in the range of 5% to 40%. The atom concentration of carbon can be set to be in the range of 5% to 50%.

The work function material layer can be formed by atomic layer deposition (ALD), physical vapor deposition (PVD), or chemical vapor deposition (CVD). It is preferable that the work function material layer is formed so as to cover the gate electrode, and the film thickness thereof is preferably 100 nm or less, more preferably 50 nm or less, and still more preferably in the range of 1 nm to 10 nm.

Among these, in the present invention, it is preferable to use a substrate in which a layer of TiAlC is employed from a viewpoint of suitably expressing selectivity of etching.

In the element of the present embodiment, the gate dielectric layer is formed of a high-k material containing a metal and oxygen. A known material can be used as the high-k gate dielectric material. The layer can be allowed to be deposited using a normal method. Examples thereof include chemical vapor deposition (CVD), physical vapor deposition (PVD), molecular beam deposition (MBD), pulsed laser deposition (PLD), liquid raw material mist chemical deposition (LSMCD), and atomic layer deposition (ALD). Examples of the typical high-k dielectric material include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, SrTiOₓN), LaAlOₓN₃, and Y₂OₓN_{y}. x is in the range of 0.5 to 3 and y is in the range of 0 to 2. The thickness of the gate dielectric layer is preferably in the range of 0.9 nm to 6 nm and more preferably in the range of 1 nm to 3 nm. Among these, it is preferable that the gate dielectric layer is formed of hafnium oxide (HfO₂).

Other members or structures can be formed by a normal method according to appropriate normal materials. Specifically, US2013/0214364A and US2013/0341631A can be referenced and the contents of which are incorporated by reference.

In the etching solution according to the preferred embodiment of the present invention, even in a case of a substrate whose work function material layer described above is exposed, metals (Ni, Pt, Ti, and the like) of the first layer can be effectively removed while suppressing damage of the layer.

[Etching Solution]

Next, a preferred embodiment of the etching solution of the present invention will be described. The etching solution of the present embodiment contains an organic alkali compound and an oxidant as needed. Hereinafter, respective components including arbitrary components will be described below.

(Organic Alkali Compound)

The organic alkali compound is a compound having carbon atoms and exhibiting alkalinity. It is preferable that the organic alkali compound is (a) a hydrocarbon amine compound having 3 or more carbon atoms, (b) an amine compound containing an oxygen atom or a sulfur atom, or (c) an ammonium compound having 5 or more carbon atoms or an ammonium compound having an oxygen atom or a sulfur atom. Here, the amine compound is a compound containing a primary amine, a secondary amine, a tertiary amine, or salts thereof. The amine compound contains a carbamoyl group and a salt thereof. The ammonium group also means a quaternary ammonium group or a salt thereof.

Here, examples of the hydrocarbon group of the amine compound (a) include an alkane residue (an alkane residue is typically an alkyl group, but may be a divalent or higher valent group (same applies to other residues)), an alkene residue, an aryl residue, or a combination of these.

The number of carbon atoms of the hydrocarbon amine compound (a) is 3 or more and the upper limit thereof is substantively 16 or lower.

As the hydrocarbon amine (a), a compound represented by any of the following Formulae (O-1) to (O-3) is exemplified.

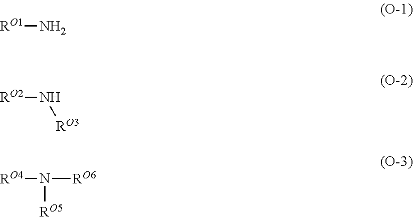

In the formulae, R⁰¹ represents an alkyl group (the number of carbon atoms is preferably in the range of 3 to 12, more preferably in the range of 4 to 12, and still more preferably in the range of 5 to 12), an alkenyl group (the number of carbon atoms is preferably in the range of 1 to 12 and more preferably 3 to 12), an alkynyl group (the number of carbon atoms is preferably in the range of 1 to 12 and more preferably in the range of 3 to 12), or an aryl group (the number of carbon atoms is preferably in the range of 6 to 14). R⁰² to R⁰⁶ each independently represent an alkyl group (having 1 to 12 carbon atoms), an alkenyl group (having 1 to 12 carbon atoms), an alkynyl group (having 1 to 12 carbon atoms), or an aryl group (having 6 to 14 carbon atoms). In this case, the alkyl group, the alkenyl group, the alkynyl group, or the aryl group herein may further include an amino group, but does not include a substituent having an oxygen atom or a sulfur atom.

Specific examples of the hydrocarbon amine compound (a) include cyclohexylamine, pentylamine, benzylamine, n-hexylamine, 2-ethylhexylamine, and octylamine.

It is preferable that the amine compound (b) including an oxygen atom or a sulfur atom is a compound which includes a substituent containing a hydrocarbon group and an oxygen atom or a sulfur atom as defined above. Examples of the substituent or the linking group having a heteroatom include a hydroxy group (OH), a carboxyl group (COOH), a sulfanyl group (SH), an ether group (O), a thioether group (S), and a carbonyl group (CO). The number of carbon atoms of the amine compound (b) is one or more and the upper limit thereof is substantively 16 or lower.

As the amine compound (b) having a heteroatom, a compound represented by any of the following Formulae (P-1) to (P-3) is exemplified.

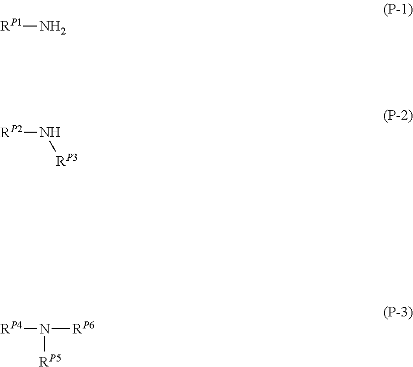

In the formulae, R^{P1} to R^{P6} each independently represent an acyl group (the number of carbon atoms is preferably in the range of 1 to 6), an alkoxy group (the number of carbon atoms is preferably in the range of 1 to 6), an alkoxycarbonyl group (the number of carbon atoms is in the range of preferably 2 to 6), an alkoxycarbonylamino group (the number of carbon atoms is preferably in the range of 2 to 6), a group represented by the following Formula (x), an alkyl group (the number of carbon atoms is preferably in the range of 1 to 6), an alkenyl group (the number of carbon atoms is preferably in the range of 2 to 6), an alkynyl group (the number of carbon atoms is preferably in the range of 2 to 6), an aryl group (the number of carbon atoms is preferably in the range of 6 to 10), or a heterocyclic group (having 2 to 6 carbon atoms). In this case, R^{P}1 in Formula (P-1) does not represent a hydrocarbon group (an alkyl group, an alkenyl group, an alkynyl group, or an aryl group). Both of R^{P2} and R^{P3} in Formula (P-2) do not represent a hydrocarbon group (an alkyl group, an alkenyl group, an alkynyl group, or an aryl group). In Formula (P-3), all of R^{P4} to R^{P6} do not represent a hydrocarbon group (an alkyl group, an alkenyl group, an alkynyl group, or an aryl group).

These groups may further include a substituent T. Preferred examples of an optional substituent to be added include a hydroxy group (OH), a carboxyl group (COOH), a sulfanyl group (SH), an alkoxy group, and a thioalkoxy group. In addition, each of an alkyl group, an alkenyl group, and an alkynyl group may include 1 to 4 O's, S's, CO's, and NR^{N}'s respectively.

X1-(Rx1-X2)mx-Rx2-* (X)

X1 represents a hydroxy group, a sulfanyl group, an alkoxy group having 1 to 4 carbon atoms, or a thioalkoxy group having 1 to 4 carbon atoms. Rx1 and Rx2 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these. X2 represents O, S, CO, NR^{N} (R^{N} represents a hydrogen atom or an alkyl group having 1 to 6 carbon atoms). mx represents an integer of 0 to 6. When mx is 2 or greater, a plurality of Rx1 's and X2's may be different from each other. Rx1 and Rx2 may further include a substituent T. The symbol “*” indicates an atomic bond.

Specific examples of the amine compound (b) including an oxygen atom or a sulfur atom include methyl carbazic acid, O-methylhydroxylamine, N-methylhydroxylamine, monoethanolamine, 3-ethoxypropyl amine, diglycolamine, triethanolamine, diethanolamine, monoethanolamine, N-methylethanolamine, N,N-diethylmonoethanolamine, diethylhydroxylamine, isopropanolamine, diisopropanolamine, and 2-(methylamino)ethanol.

Examples of the onium compound (c) include a nitrogen-containing onium compound (quaternary ammonium salt or the like), a phosphorus-containing onium compound (quaternary phosphonium salt or the like), and a sulfur-containing onium compound (for example, SRy₃M: Ry represents an alkyl group having 1 to 6 carbon atoms and M represents a counterion). Among these, a nitrogen-containing onium compound (a quaternary ammonium salt, a pyridinium salt, a pyrazolium salt, or an imidazolium salt) is preferable. As the alkali compound, quaternary ammonium hydroxide is preferable.

As the onium compound (c), a compound represented by the following Formula (Q-1) is exemplified.

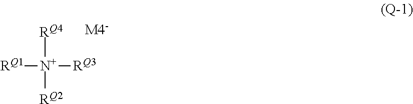

In the formula, R^{Q1} to R^{Q4} each independently represent an alkyl group having 1 to 20 carbon atoms, an alkenyl group having 2 to 20 carbon atoms, an alkynyl group having 2 to 20 carbon atoms, an aryl group having 6 to 14 carbon atoms, an aralkyl group having 7 to 14 carbon atoms, or a group represented by the following Formula (y). In this case, when the total number of carbon atoms of R^{Q1} to R^{Q4} is 5 or more or the total number of carbon atoms of R^{Q1} to R^{Q4} is 4, any one of R^{Q1} to R^{Q4} includes a substituent having an oxygen atom or a sulfur atom.

Y1-(Ry1-Y2)my-Ry2-* (y)

Y1 represents an alkyl group having 1 to 12 carbon atoms, an alkenyl group having 2 to 12 carbon atoms, an alkynyl group having 2 to 12 carbon atoms, an aralkyl group having 7 to 14 carbon atoms, an aryl group having 6 to 14 carbon atoms, a hydroxy group, a sulfanyl group, an alkoxy group having 1 to 4 carbon atoms, or a thioalkoxy group having 1 to 4 carbon atoms. Y2 represents O, S, CO, or NR^{N} (R^{N} represents a hydrogen atom or an alkyl group having 1 to 6 carbon atoms). Ry1 and Ry2 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these. my represents an integer of 0 to 6. When my is 2 or greater, a plurality of Ry1's and Y2's may be different from each other. Ry1 and Ry2 may further include a substituent T. The symbol “*” indicates an atomic bond.

The total carbon atoms of R^{Q1} to R^{Q4} is preferably 6 or greater, more preferably 8 or greater, and particularly preferably 12 or greater. The upper limit thereof, which is not particularly limited, is preferably 40 or less and more preferably 30 or less.

M4⁻ represents a counterion such as a hydroxide ion or the like.

Specifically, tetraalkylammonium hydroxide (the number of carbon atoms is preferably in the range of 4 to 25, but it is preferable to include a substituent containing an oxygen atom or a sulfur atom when the number of carbon atoms thereof is 4) is preferable. At this time, an arbitrary substituent (for example, a hydroxyl group, an allyl group, or an aryl group) may be substituted with an alkyl group within a range not damaging the effects of the present invention. Further, the alkyl group may be linear, branched, or cyclic. Specific examples thereof include tetramethylammonium hydroxide (TMAH), tetraethylammonium hydroxide (TEAH) (it is preferable to include a substituent containing an oxygen atom or a sulfur atom), benzyl trimethyl ammonium hydroxide, ethyl trimethyl ammonium hydroxide, 2-hydroxyethyl trimethyl ammonium hydroxide, benzyl triethyl ammonium hydroxide, hexadecyl trimethyl ammonium hydroxide, tetrabutyl ammonium hydroxide (TBAH), tetrahexyl ammonium hydroxide (THAH), and tetrapropyl ammonium hydroxide (TPAH). Other examples thereof include benzalkonium chloride, benzethonium chloride, methylbenzethonium chloride, cetylpyridinium chloride, cetrimonium, dofanium chloride, tetraethylammonium bromide, didecyl dimethyl ammonium chloride, and domiphen bromide.

Nitrogen-Containing Polymer

It is also preferable that the above-described organic alkali compound is the following nitrogen-containing polymer. The nitrogen-containing polymer contains relatively small molecules when the nitrogen-containing polymer is a compound including a plurality of repeating units having a nitrogen atom (see compounds A-15 to A-17 in the following example). It is preferable that the repeating unit includes a primary amine structure (—NRx₂), a secondary amine structure (>NRx), a tertiary amine structure (>N—), or a quaternary ammonium structure (>N⁺<) (these structures are collectively referred to as a “specific amine structure” and the repeating unit is referred to as a “specific amine repeating unit”). Rx represents a hydrogen atom or an alkyl group having 1 to 6 carbon atoms.

As the nitrogen-containing polymer, a cation surfactant having a hydrophilic nitrogen-containing group and a hydrophobic terminal group is exemplified. It is preferable that the nitrogen-containing polymer includes a repeating unit having the specific amine structure. More specifically, it is preferable that the nitrogen-containing polymer contains a repeating unit having a functional group selected from the group consisting of an amino group (—NRx₂), an amide group (—CONRx-), an imide group (—CONRxCO—), an imino group (—NRx-), an alkyleneimino group (—N(Rx)Lx-: Lx represents an alkylene group having 1 to 6 carbon atoms), and a hydroxyalkyleneimino group ((—NRx)Ly-: Ly represents an alkylene group including a hydroxy group having 1 to 6 carbon atoms).

The number of specific amine repeating units existing in the nitrogen-containing polymer is 40% or greater and more preferably 50% or greater of the total number of repeating units. The upper limit thereof is not particularly limited, but 100% or less of the total number of repeating units is preferable. The number of specific amine repeating units is preferably 2 to 1000 and more preferably 3 to 200 in a molecule.

The nitrogen-containing polymer may be a homopolymer containing the above-described repeating unit or may be a copolymer. Alternatively, the nitrogen-containing polymer may further include another repeating unit (preferably a non-ionic repeating unit). Examples of another repeating unit include an ethylene oxide group, a propylene oxide group, or a repeating unit derived from styrene. The number of non-ionic repeating units existing in a polyelectrolyte is preferably 99% or less and more preferably 90% or less of the total number of repeating units. The lower limit thereof is not particularly limited, but may be 0% or greater in terms such that the non-ionic repeating unit is an arbitrary repeating unit.

The nitrogen-containing polymer may further include another repeating unit. Examples of another repeating unit include a repeating unit having a hydroxy group, a phosphonic acid group (or a salt thereof), a sulfonic acid group (or a salt thereof), a phosphoric acid group (or a salt thereof), or a carboxylic acid group (or a salt thereof).

The nitrogen-containing polymer may be any of a homopolymer, a random copolymer, an alternating copolymer, a periodic copolymer, a block copolymer (for example, AB, ABA, or ABC), a graft copolymer, or a comb copolymer.

It is preferable that the specific amine repeating unit is selected from the following Formulae (a-1) to (a-8).

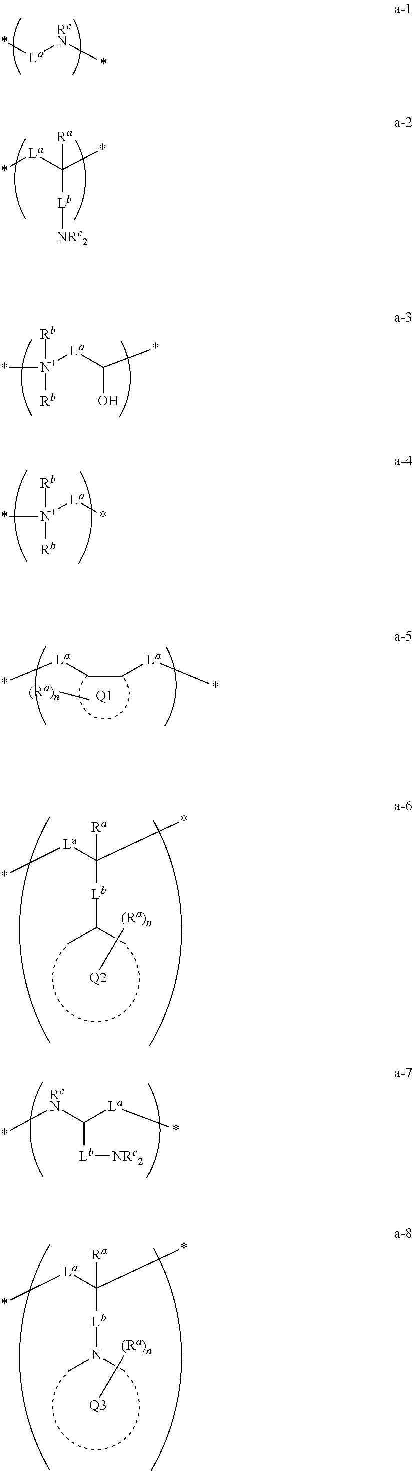

R^{a}

R^{a} represents a hydrogen atom, an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), or a heterocyclic group (the number of carbon atoms is preferably in the range of 2 to 12 and more preferably in the range of 2 to 6). Among these, it is preferable that R^{a} represents a hydrogen atom or a methyl group. In addition, an alkyl group in the present specification also means an aralkyl group.

R^{b}

R^{b} represents an alkyl group (the number of carbon atoms is preferably in the range of 1 to 12, more preferably in the range of 1 to 6, and particularly preferably in the range of 1 to 3) or an alkenyl group (the number of carbon atoms is preferably in the range of 2 to 12 and more preferably in the range of 2 to 6). Among these, it is preferable that R^{b} represents a methyl group or an ethyl group.

L^{a}

L^{a} represents an alkylene group (the number of carbon atoms is preferably in the range of 1 to 12, more preferably in the range of 1 to 6, and particularly preferably in the range of 1 to 3), a carbonyl group, an imino group (the number of carbon atoms is preferably in the range of 0 to 6 and more preferably in the range of 0 to 3), an arylene group (the number of carbon atoms is preferably in the range of 6 to 22 and more preferably in the range of 6 to 14), a heterocyclic group (the number of carbon atoms is preferably in the range of 1 to 12 and more preferably in the range of 2 to 5), or a combination of these. Among these, an alkylene group or a carbonyl group is preferable, a methylene group, an ethylene group, a propylene group, or a carbonyl group is preferable, a methylene group or an ethylene group is more preferable, and a methylene group is particularly preferable.

L^{b}

L^{b} represents a single bond, an alkylene group (the number of carbon atoms is preferably in the range of 1 to 12, more preferably in the range of 1 to 6, and particularly preferably in the range of 1 to 3), a carbonyl group, an imino group (the number of carbon atoms is preferably in the range of 0 to 6 and more preferably in the range of 0 to 3), an arylene group (the number of carbon atoms is preferably in the range of 6 to 22 and more preferably in the range of 6 to 14), a heterocyclic group (the number of carbon atoms is preferably in the range of 1 to 12 and more preferably in the range of 2 to 5), or a combination of these. Among these, a single bond, a methylene group, an ethylene group, a propylene group, or a carbonyl group is preferable and a single bond, a methylene group, or an ethylene group is preferable.

R^{c}

R^{c} represents a hydrogen atom or an alkyl group (the number of carbon atoms is preferably in the range of 1 to 12, more preferably in the range of 1 to 6, and particularly preferably in the range of 1 to 3). Among these, it is preferable that Re represents a hydrogen atom or a methyl group.

n

n represents an integer of 0 or greater. The upper limit of n is the substitutable number of respective cyclic structural portions. For example, the number is 4 in a case of the following Formulae (5-1) to (5-4) and the number is 3 in a case of Formulae (6-5) and (6-6).

A ring Q1 represents a nitrogen-containing heterocycle, and a nitrogen-containing saturated heterocycle is preferable and a nitrogen-containing saturated heterocycle of a 5- or 6-membered ring is preferable. Specifically, as the cyclic structure, the following Formulae (5-1) to (5-6) are preferable. An anion in the formulae is omitted.

A ring Q2 represents a nitrogen-containing heterocycle, and a nitrogen-containing unsaturated heterocycle is preferable, a nitrogen-containing unsaturated heterocycle of a 5- or 6-membered ring is preferable, and a pyrrolyl group, a pyrazolyl group, an imidazolyl group, a triazolyl group, a pyridyl group, or a pyrimidyl group (all of these, bonded at a C-position) is preferable. Specifically, as the cyclic structure, the following Formulae (6-1) to (6-11) are preferable.

A ring Q3 represents a nitrogen-containing heterocycle, and a nitrogen-containing unsaturated heterocycle is preferable, a nitrogen-containing unsaturated heterocycle of a 5-membered ring is more preferable, and a pyrrolyl group, an imidazolyl group, a pyrazolyl group, or a triazolyl group (all of these, bonded at a N-position) is preferable. Specifically, as the cyclic structure, the following Formulae (8-1) to (8-3) are preferable.

The symbol “*” in the formula indicates a binding position.

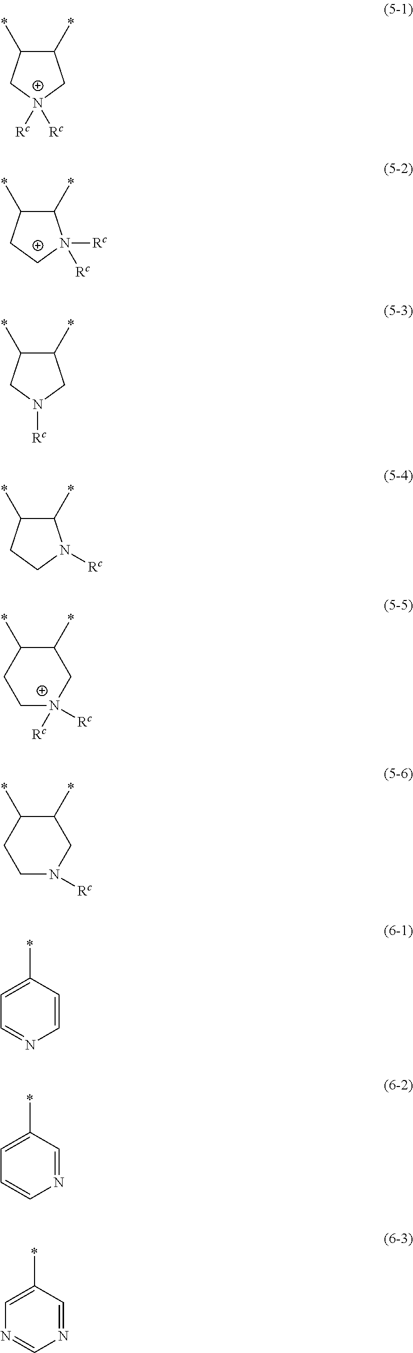

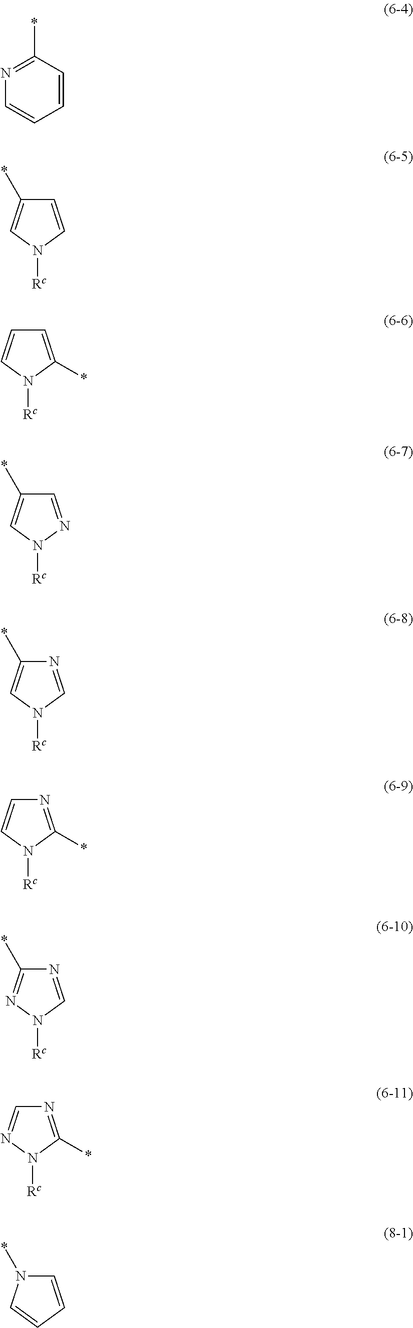

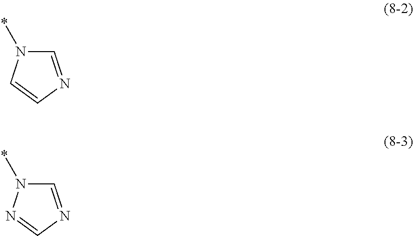 [SMILES: *n1ccnc1 ; *n1cncn1]

All of the above-described cyclic structural groups may be accompanied by a predetermined number of substituents Ra. It means that an onium in the formula may become a salt. Further, in Formulae 6-1 to 6-11 and 8-1 to 8-3, the cyclic structural group may indicate an onium or a salt thereof.

If a plurality of R^{a}s, R^{b}'s, R^{c}'s, L^{a}s, and L^{b}'s are present in a molecule, and these may be the same as or different from each other. The plurality of R^{a}'s, R^{b}'s, and R^{c}'s may be bonded to each other to form a ring. Further, although not particularly noted, substituents or linking groups adjacent to each other may be bonded to each other to form a ring within a range not damaging the effects of the present invention.

Further, it is also preferable that the nitrogen-containing polymer is a compound represented by the following Formula (b).

R^{c}₂N-[L^{d}-N(R^{c})]ₘ-L^{d}-NR^{c}₂ (b)

In the formula, R^{c} has the same definition as described above. m represents an integer of 0 or greater, and is preferably 1 or greater, more preferably 2 or greater, and still more preferably 3 or greater. The upper limit, which is not particularly limited, is substantively 10 or less and more substantively 6 or less.

L^{d} represents an alkylene group (the number of carbon atoms is preferably in the range of 1 to 12, more preferably in the range of 1 to 6, and particularly preferably in the range of 1 to 3), a carbonyl group, an imino group (the number of carbon atoms is preferably in the range of 0 to 6 and more preferably in the range of 0 to 3), an arylene group (the number of carbon atoms is preferably in the range of 6 to 22 and more preferably in the range of 6 to 14), a heterocyclic group (the number of carbon atoms is preferably in the range of 1 to 12 and more preferably in the range of 2 to 5), or a combination of these. Among these, an alkylene group is preferable, and a methylene group, an ethylene group, or a propylene group is preferable.

Further, a plurality of R^{c}'s and L^{d}'s may be the same as or different from each other. The plurality of R^{c}'s and L^{d}'s may be bonded to each other to form a ring.

It is preferable that the nitrogen-containing polymer is the following compound. In this case, the present invention is not interpreted by being limited thereto.

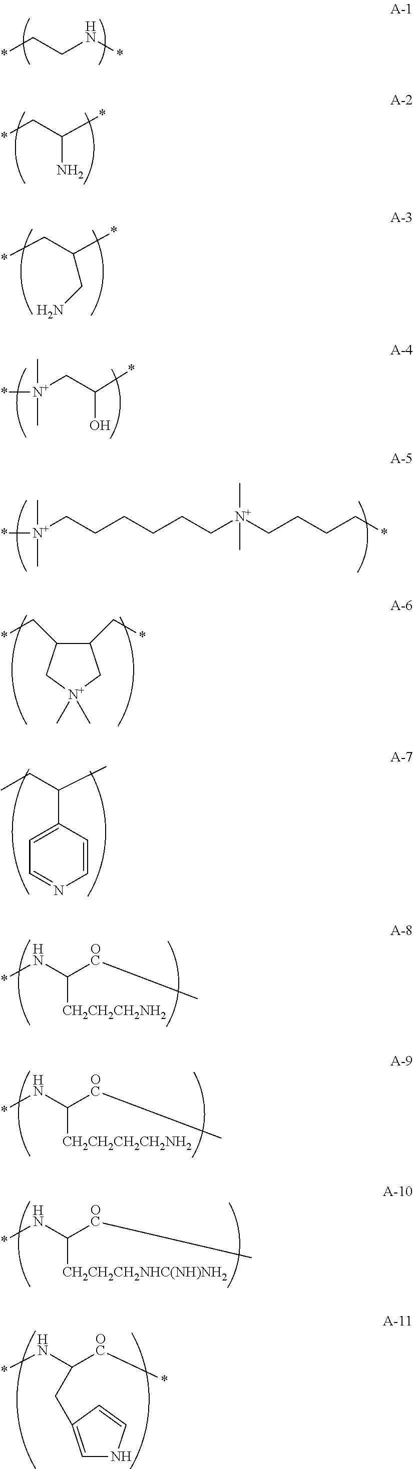

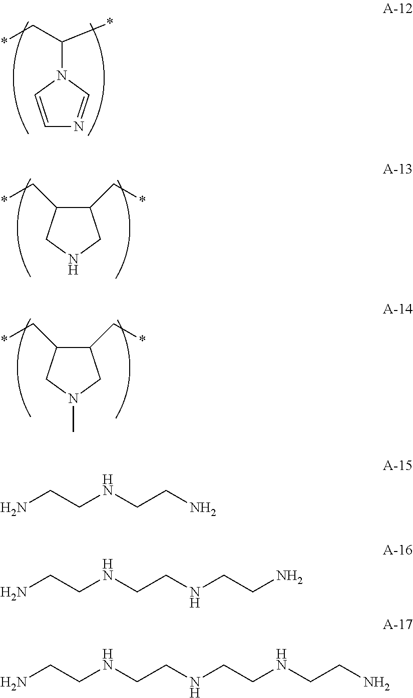

A-1: polyethyleneimine

A-2: polyvinylamine

A-3: polyallylamine

A-4: dimethylamine-epihydrin-based polymer

A-5: polyhexadimethrine

A-6: polydimethyl diallyl ammonium (salt)

A-7: poly(4-vinylpyridine)

A-8: polyornithine

A-9: polylysine

A-10: polyarginine

A-11: polyhistidine

A-12: polyvinyl imidazole

A-13: polydiallylamine

A-14: polymethyl diallylamine

A-15: diethylene triamine

A-16: triethylene tetramine

A-17: tetraethylene pentamine

A-18: pentaethylene hexamine

A commercially available product can be used as the above-described nitrogen-containing polymer.

The concentration of the nitrogen-containing polymer in the etching solution, which is not particularly limited, is preferably 0.0001% by mass or greater, more preferably 0.0005% by mass or greater, and particularly preferably 0.001% by mass or greater. The upper limit thereof is not particularly limited, but is preferably 5% by mass or less, more preferably 2% by mass or less, and particularly preferably 1% by mass or less. It is preferable that the concentration thereof is greater than or equal to the lower limit described above because the dissolution rate of a titanium-containing layer can be controlled. It is preferable that the concentration thereof is less than or equal to the upper limit described above from a viewpoint of the capability of suppressing deposition of the nitrogen-containing polymer. The nitrogen-containing polymer may be used alone or in combination of two or more kinds thereof.

Moreover, it is assumed that the nitrogen-containing polymer achieves excellent selectivity while a protective film is formed on the titanium-containing layer using nitrogen as an adsorption point.

The molecular weight of the nitrogen-containing polymer, which is not particularly limited, is preferably 100 or greater and more preferably 200 or greater. The upper limit thereof is preferably 100000 or less, more preferably 50000 or less, still more preferably 20000 or less, and particularly preferably 10000 or less. The molecular weight thereof is substantively greater than or equal to the lower limit described above. Meanwhile, from a viewpoint of the capability of suppressing deposition of the nitrogen-containing polymer, it is preferable that the molecular weight thereof is less than or equal to the upper limit described above. In the present invention, the ratio (η) of the etching rate can be effectively changed by changing the condition within the range of the molecular weight described above. The details will be described below.

The molecular weight of the nitrogen-containing polymer is a value measured using the following method unless otherwise noted.

—Measuring molecular weight—

The molecular weight calculated from the chemical structure described in the catalog is applied to a commercially available compound. In a case where the chemical structure is unclear or the like, a method for performing column separation by LC-MS and then determining the molecular weight using mass spectrometry is used. In a case where mass spectrometry analysis is difficult to be performed because the molecular weight is large, the weight average molecular weight in terms of polystyrene is measured by GPC. The weight average molecular weight is measured using a GPC device HLC-8220 (manufactured by TOSOH CORPORATION), THF (tetrahydrofuran, manufactured by Shonan Wako Junyaku) as an eluent, and G3000HXL+G2000HXL as a column. The flow rate at 23° C. is 1 mL/min and detected by RI.

The concentration of the organic alkali compound in the etching solution is preferably 3% by mass or greater, more preferably 5% by mass or greater, and particularly preferably 10% by mass or greater. The upper limit thereof is preferably 100% by mass or less, more preferably 80% by mass or less, and particularly preferably 60% by mass or less. It is preferable that the concentration of the alkali compound is in the above-described range because damage of the germanium-containing layer (first layer) and the germanium silicide layer (third layer) is effectively suppressed while excellent etching properties of the metal layer (second layer) is maintained. When the alkali compound is in a liquid state at an application temperature, 100% by mass of the organic alkali compound can be applied, and this is one of the preferred embodiments of the present invention.

Moreover, in the present invention, the organic alkali compound may be used alone or in combination of two or more kinds thereof. The “combination of two or more kinds thereof” means that two or more kinds of compounds having chemical structures even slightly different from each other are used. For example, Formula (O-1) described above corresponds to this case, a case of two kinds of compounds whose portions corresponding to an atomic group R⁰¹ are different from each other is also included. In the case where two or more kinds are used in combination, the combination ratio thereof is not particularly limited, and the total amount used is preferably in the above-described concentration range as the sum of two or more alkali compounds.

(Oxidant)

It is preferable that the etching solution according to the present embodiment contains an oxidant. Preferred examples of the oxidant include nitric acid and hydrogen peroxide.

The concentration of the oxidant contained in the etching solution is preferably 0.1% by mass or greater, more preferably 1% by mass or greater, and particularly preferably 2% by mass or greater. The upper limit thereof is preferably 30% by mass or less, more preferably 25% by mass or less, and particularly preferably 20% by mass or less.

It is preferable that the content of the oxidant is in the above-described range because damage of the germanium-containing layer (first layer) or the germanium silicide layer (third layer) is effectively suppressed while excellent etching properties of the metal layer (second layer) is maintained. The oxidant may be used alone or in combination of two or more kinds thereof.

(Specific Organic Additive)

It is preferable that the etching solution according to the present embodiment contains a specific organic additive. The organic additive is formed of an organic compound containing a nitrogen atom, a sulfur atom, a phosphorous atom, or an oxygen atom. Among these, it is preferable that the organic additive is a compound including a substituent or a linking group selected from an amino group (—NH₂) or a salt thereof, an imino group (—NR^{N}—) or a salt thereof, a sulfanyl group (—SH), a hydroxy group (—OH), a carbonyl group (—CO—), a sulfonic acid group (—SO₃H) or a salt thereof, a phosphoric acid group (—PO₄H₂) or a salt thereof, an onium group or a salt thereof, a sulfinyl group (—SO—), a sulfonyl group (SO₂), an ether group (—O—), an amine oxide group, and a thioether group (—S—). Further, it is also preferable that the organic additive is an aprotic dissociable organic compound (an alcohol compound, an ether compound, an ester compound, or a carbonate compound), an azole compound, a betaine compound, a sulfonic acid compound, an amide compound, an onium compound, an amino acid compound, a phosphoric acid compound, a sulfonic acid compound, or a sulfoxide compound.

R^{N} of the amino group represents a hydrogen atom or a substituent. As the substituent, an alkyl group (the number of carbon atoms is preferably in the range of 1 to 24 and more preferably in the range of 1 to 12), an alkenyl group (the number of carbon atoms is preferably in the range of 2 to 12 and more preferably in the range of 2 to 6), an alkynyl group (the number of carbon atoms is preferably in the range of 2 to 24 and more preferably in the range of 2 to 12), an aryl group having 6 to 10 carbon atoms, or an aralkyl group having 7 to 11 carbon atoms is preferable.

It is particularly preferable that the specific organic additive is formed of a compound represented by the following Formulae (I) to (XII).

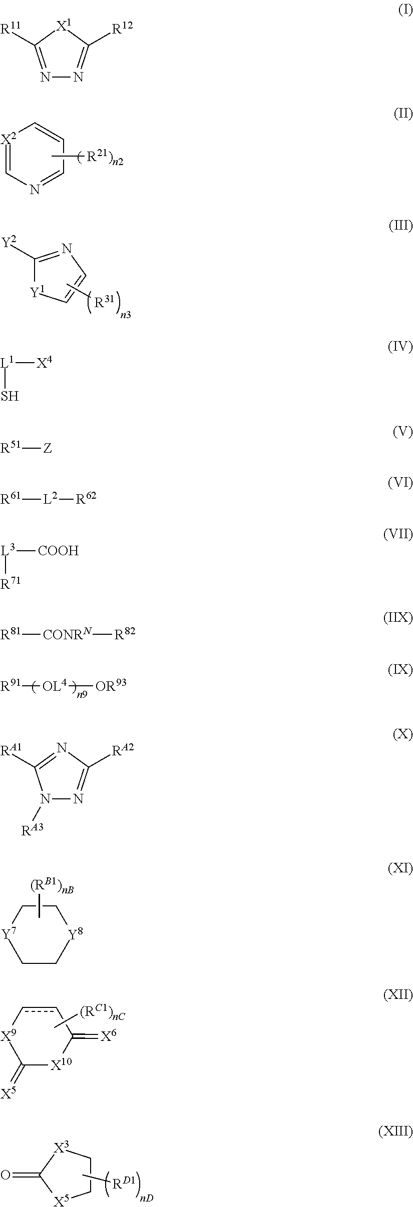

Formula (I): R¹¹ and R¹² each independently represent a hydrogen atom, an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), an aralkyl group (the number of carbon atoms is preferably in the range of 7 to 23 and more preferably in the range of 7 to 15), a sulfanyl group (SH), a hydroxy group (OH), or an amino group (—NR^{N}—). In this case, at least one of R¹¹ and R¹² represents a sulfanyl group, a hydroxy group, or an amino group (the number of carbon atoms is preferably in the range of 0 to 6 and more preferably in the range of 0 to 3). Further, when the above-described substituents further include other substituents (an alkyl group, an alkenyl group, and an aryl group), an arbitrary substituent T may be further included. The same applies to a substituent or a linking group described below.

X¹ represents a methylene group (CR^{C}₂), a sulfur atom (S), or an oxygen atom (O). R^{C} represents a hydrogen atom or a substituent (the substituent T described below is preferable).

Formula (II): X² represents a methine group (═CR^{C}—) or a nitrogen atom (N). R²¹ represents a substituent (the substituent T described below is preferable). Among these, a sulfanyl group (SH), a hydroxy group (OH), or an amino group (NR^{N}₂) is preferable.

n2 represents an integer of 0 to 4.

When a plurality of R²¹'s are present, R²¹'s may be the same as or different from each other and may be bonded or condensed to each other to form a ring.

Formula (III): Y¹ represents a methylene group, an imino group (NR^{N}), or a sulfur atom (S).

Y² represents a hydrogen atom, an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), an aralkyl group (the number of carbon atoms is preferably in the range of 7 to 23 and more preferably in the range of 7 to 15), an amino group (the number of carbon atoms is preferably in the range of 0 to 6 and more preferably in the range of 0 to 3), a hydroxy group, or a sulfanyl group.

R³¹ represents a substituent (the substituent T described below is preferable). Among these substituents, a sulfanyl group (SH), a hydroxy group (OH), or an amino group (NR^{N}₂) is preferable.

n3 represents an integer of 0 to 2.

When a plurality of R³¹'s are present, R³¹'s may be the same as or different from each other and may be bonded or condensed to each other to form a ring. As the ring to be formed, a 6-membered ring is preferable and examples thereof include rings having a benzene structure or a 6-membered heteroaryl structure.

It is preferable that Formula (III) is Formula (III-1) below.

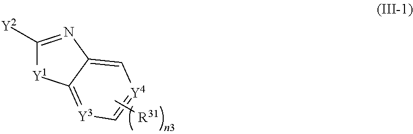

Y³ and Y⁴ each independently represent a methine group (═CR^{C}—) or a nitrogen atom (N).

Y¹, Y², R³¹, and n3 have the same definitions as those described above. The positions of Y³ and Y⁴ may be different in a 6-membered ring.

Formula (IV): L¹ represents an alkylene group (the number of carbon atoms is preferably in the range of 1 to 12, more preferably in the range of 1 to 6, and particularly preferably in the range of 1 to 3), an alkynylene group (the number of carbon atoms is preferably in the range of 2 to 12 and more preferably in the range of 2 to 6), an alkenylene group (the number of carbon atoms is preferably in the range of 2 to 12 and more preferably in the range of 2 to 6), an arylene group (the number of carbon atoms is preferably in the range of 6 to 22 and more preferably in the range of 6 to 14), or an aralkylene group (the number of carbon atoms is preferably in the range of 7 to 23 and more preferably in the range of 7 to 15).

X⁴ represents a carboxyl group or a hydroxy group.

Formula (V): R⁵¹ represents an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), or an aralkyl group (the number of carbon atoms is preferably in the range of 7 to 23 and more preferably in the range of 7 to 15).

When R⁵¹ represents an aryl group, it is preferable that an alkyl group having 1 to 20 carbon atoms, an alkenyl group having 2 to 20 carbon atoms, or an alkynyl group having 2 to 20 carbon atoms is substituted therewith.

When R⁵¹ represents an alkyl group, the structure thereof may be as follows.

*—R⁵²—(R⁵³—Y⁵³)ₙ₅—R⁵⁴

R⁵² is a single bond or a linking group which has the same definition as that for L¹. R⁵³ is a linking group which has the same definition as that for L¹. Y⁵³ represents an oxygen atom (O), a sulfur atom (S), a carbonyl group (CO), or an imino group (NR^{N}). R⁵⁴ represents an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), or an aralkyl group (the number of carbon atoms is preferably in the range of 7 to 23 and more preferably in the range of 7 to 15).

n5 represents an integer of 0 to 8.

R⁵¹ may further include a substituent T and, among these, a sulfanyl group (SH), a hydroxy group (OH), or an amino group (NR^{N}₂) is preferable.

Z represents an amino group (the number of carbon atoms is preferably in the range of 0 to 6 and more preferably in the range of 0 to 3), a sulfonic acid group, a phosphoric acid group, a carboxyl group, a hydroxy group, a sulfanyl group, or an amine oxide group (—NH₂⁺O⁻).

In the present invention, an amino group, a sulfonic acid group, a phosphoric acid group, or a carboxyl group may form an acid ester (for example, an alkyl ester having 1 to 6 carbon atoms) unless otherwise noted in a case of a salt or an acid thereof.

When Formula (V) represents a carboxylic acid, it is preferable that R⁵³ represents an alkyl group. In this case, the number of carbon atoms is preferably in the range of 1 to 24, more preferably in the range of 3 to 20, still more preferably in the range of 6 to 18, and particularly preferably in the range of 8 to 16. The alkyl group may further include a substituent T and this is the same as those described above. When Formula (V) is a fatty acid, it is preferable that the number of carbon atoms is relatively large as described above. It is considered that this is because protection properties of germanium and the silicide layer are more effectively exhibited when appropriate hydrophobicity is imparted to the additive.

It is preferable that the compound represented by Formula (V) is any one of compounds represented by the following Formulae (V-1) to (V-3). In the formulae, Z¹ and Z² represent a sulfonic acid group with a linking group L interposed therebetween. R⁵⁶ represents a substituent T and, among the examples described above, an alkyl group is preferable. n⁵¹ and n⁵⁶ represent an integer of 0 to 5. n⁵³ represents an integer of 0 to 4. The maximum values of n⁵¹, n⁵³, and n⁵⁶ are increased or decreased according to the number of Z¹ or Z² in the same ring. n⁵² represents an integer of 1 to 6 and is preferably 1 or 2. n⁵⁴ and n⁵⁵ each independently represent an integer of 0 to 4 and n⁵⁴+n⁵⁵ is 1 or greater. n⁵⁴+n⁵⁵ is preferably 1 or 2. n⁵⁷ and n⁵⁸ each independently represent an integer of 0 to 5 and n⁵⁷+n⁵⁸ is 1 or greater. n⁵⁷+n⁵⁸ is preferably 1 or 2. A plurality of R⁵⁶'s may be the same as or different from each other. A linking group L is preferably L¹, L², or a combination of these and more preferably L¹.

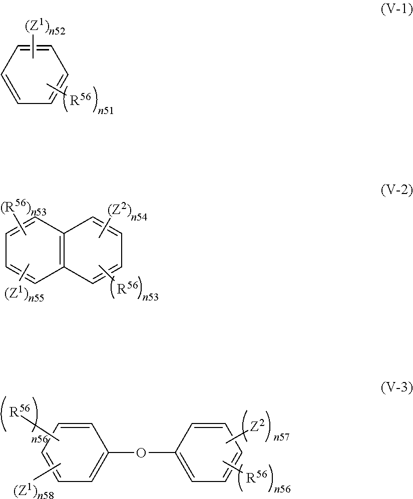

Formula (VI): R⁶¹ and R⁶² each independently represent an alkyl group (the number of carbon atoms is preferably in the range of 1 to 12, more preferably in the range of 1 to 6, and particularly preferably in the range of 1 to 3), an aryl group (the number of carbon atoms is preferably in the range of 6 to 22 and more preferably in the range of 6 to 14), an alkoxy group (the number of carbon atoms is preferably in the range of 1 to 12, more preferably in the range of 1 to 6, and particularly preferably in the range of 1 to 3), or an alkylamino group (the number of carbon atoms is preferably in the range of 1 to 12, more preferably in the range of 1 to 6, and particularly preferably in the range of 1 to 3). R⁶¹ and R⁶² may be bonded or condensed to each other to form a ring. When R⁶¹ or R⁶² represents an alkyl group, the alkyl group may be a group represented by *—R⁵²—(R⁵³—Y⁵³)—R⁵⁴.

L² represents a carbonyl group, a sulfinyl group (SO), or a sulfonyl group (SO₂).

The compound represented by Formula (VI) is preferably a compound represented by any of the following Formulae (VI-1) to (VI-3). In the formulae, R⁶¹ and R⁶² have the same definitions as those described above. Q⁶ is a 3- to 8-membered ring, preferably a 5- or 6-membered ring, more preferably a saturated 5- or 6-membered ring, and particularly preferably a 5- or 6-membered ring of saturated hydrocarbon. In this case, Q⁶ may include an arbitrary substituent T.

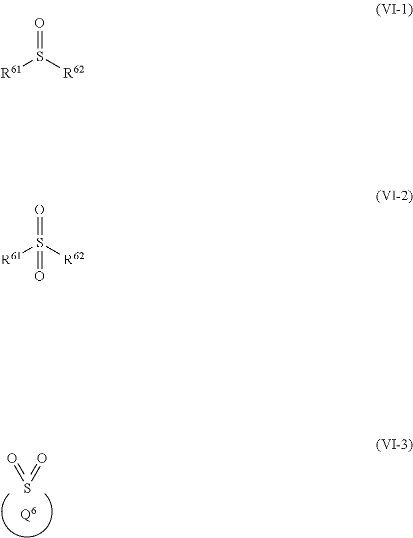

Formula (VII): R⁷¹ represents an amino group (—NR^{N}₂), or an ammonium group (—NR^{N}₃⁺.M⁻).

L³ represents a single bond or the same group as that for L¹. Among these, preferably, L³ represents a methylene group, an ethylene group, a propylene group, or (-L³¹(SR^{S})). L³¹ represents an alkylene group having 1 to 6 carbon atoms. R^{S} may form a disulfide group at a hydrogen atom or at this site to be dimerized.

Formula (IIX): R⁸¹ and R⁸² each independently represent an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), or an aralkyl group (the number of carbon atoms is preferably in the range of 7 to 23 and more preferably in the range of 7 to 15).

Formula (IX): L⁴ represents the same group as that for L¹.

R⁹¹ and R⁹³ each independently represent a hydrogen atom, an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), an acyl group (the number of carbon atoms is preferably in the range of 2 to 12 and more preferably in the range of 2 to 6), or an aralkyl group (the number of carbon atoms is preferably in the range of 7 to 23 and more preferably in the range of 7 to 15). In this case, when n9 represents 0, both of R⁹¹ and R⁹³ do not represent a hydrogen atom.

n9 represents an integer of 0 to 100, is preferably in the range of 0 to 50, more preferably in the range of 0 to 25, still more preferably in the range of 0 to 15, even still more preferably in the range of 0 to 10, and particularly preferably in the range of 0 to 5.

The compound represented by Formula (IX) is more preferably a compound represented by the following Formula (IX-1).

R⁹¹—(OL⁴¹)-(OL⁴)ₙ₉₁-OR⁹³ (IX-1)

It is preferable that L⁴¹ represents an alkylene group having 2 or more carbon atoms and the number of carbon atoms is preferably in the range of 2 to 6. Due to the setting of the carbon atoms of the alkylene group, it is assumed that a specific adsorption state with a metal (for example, Ti) is not formed and the removal thereof is not inhibited. Further, it is assumed that a binding component of a metal and a fluorine atom behaves in a hydrophilic or hydrophobic manner and a compound which connects oxygen atoms and has 2 or 3 carbon atoms suitably acts. From this viewpoint, the number of carbon atoms of L⁴¹ is preferably 3 or greater, preferably in the range of 3 to 6, and particularly preferably 3 or 4. Moreover, in regard to the number of carbon atoms of L⁴¹, the carbon atoms included in a branch are excluded and the number of linked carbon atoms is preferably 2 or greater in a case of the alkylene group of a branch. For example, the number of linked carbon atoms in a 2,2-propanediyl group is 1. That is, the number of carbon atoms connecting O—O is referred to as the number of linked carbon atoms and a group having 2 or more linked carbon atoms is preferable. When an adsorption action with the above-described metals is considered, the number of linked carbon atoms is preferably 3 or greater, more preferably in the range of 3 to 6, and particularly preferably in the range of 3 to 4.

The number of linked carbon atoms of n91 is the same as that of n9.

When the present compound is a compound having two or more hydroxy groups of hydrogen atoms in R⁹¹ and R⁹³, it is preferable that the structure thereof is represented by the following Formula (IX-2).

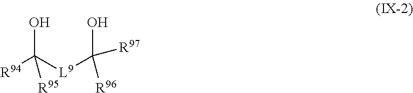

R⁹⁴ to R⁹⁷ in the formula have the same definitions as those for R⁹¹. R⁹⁴ to R⁹⁷ may further include a substituent T and, for example, may include a hydroxy group. L⁹ represents an alkylene group, and the number of carbon atoms thereof is preferably in the range of 1 to 6 and more preferably in the range of 1 to 4. Specific examples of the compound represented by Formula (IX-2) include hexylene glycol, 1,3-butanediol, and 1,4-butanediol.

From a viewpoint of hydrophilicity and hydrophobicity, it is preferable that a compound whose CLogP value is in a desired range is used as the compound represented by Formula (IX). The CLogP value of the compound represented by Formula (IX) is preferably −0.4 or greater and more preferably −0.2 or greater. The upper limit thereof is preferably 2 or less and more preferably 1.5 or less.

ClogP

An octanol/water partition coefficient (log P value) can be normally measured using a flask immersion method described in JIS Japanese Industrial Standards Z7260-107 (2000). Further, the octanol/water partition coefficient (log P value) can be estimated by a calculating chemical method or an empirical method instead of actual measurement. It is known that a Crippen's fragmentation method (J. Chem. Inf. Comput. Sci., 27, 21 (1987)), a Viswanadhan's fragmentation method (J. Chem. Inf. Comput. Sci., 29, 163 (1989)), Broto's fragmentation method (Eur. J. Med. Chem. —Chim. Theor., 19, 71 (1984)), or the like is used as the calculation method thereof. In the present invention, the Crippen's fragmentation method (J. Chem. Inf. Comput. Sci., 27, 21 (1987)) is used.

The ClogP value is obtained by calculating a common logarithm log P of a partition coefficient P to 1-octanol and water. A known method or known software can be used for calculating the ClogP value, but, unless otherwise noted, a system from Daylight Chemical Information System, Inc. and a ClogP program incorporated in PCModels are used in the present invention.

Formula (X): R^{A3} has the same definition as that for R^{N}. R^{A1} and R^{A2} each independently represent a hydrogen atom, an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), an aralkyl group (the number of carbon atoms is preferably in the range of 7 to 23 and more preferably in the range of 7 to 15), a sulfanyl group, a hydroxy group, or an amino group. In this case, it is preferable that at least one of R^{A1} and R^{A2} is a sulfanyl group, a hydroxy group, or an amino group (the number of carbon atoms is preferably in the range of 0 to 6 and more preferably in the range of 0 to 3).

Formula (XI): Y⁷ and Y⁸ each independently represent an oxygen atom, a sulfur atom, an imino group (NR^{N}), or a carbonyl group. R^{B1} represents a substituent (hereinafter, a substituent T is preferable). nB represents an integer of 0 to 8. However, any one of Y⁷ and Y⁸ may be a methylene group (CR^{C}₂).

Formula (XII): Y⁹ and Y¹⁰ each independently represent an oxygen atom, a sulfur atom, a methylene group (CR^{C}₂), an imino group (NR^{N}), or a carbonyl group. The positions of Y⁹ and Y¹⁰ may be different in a 6-membered ring.

X⁵ and X⁶ each independently represent a sulfur atom or an oxygen atom. The broken line means that the bond may be a single bond or a double bond. R^{C1} represents a substituent (hereinafter, a substituent T is preferable). nC represents an integer of 0 to 2.

When a plurality of R^{C1}'s are present, the plurality of R^{C1}'s may be the same as or different from each other and may be bonded or condensed to each other to form a ring.

Formula (XIII): X³ represents an oxygen atom, a sulfur atom, or an imino group (NR^{M}). R^{M} represents a hydrogen atom or an alkyl group having 1 to 24 carbon atoms, and is preferably an alkyl group having 2 to 20 carbon atoms, more preferably an alkyl group having 4 to 16 carbon atoms, and particularly preferably an alkyl group having 6 to 12 carbon atoms.

X⁵ represents an oxygen atom, a sulfur atom, an imino group (NR^{M}), or a methylene group (CR^{C}₂).

R^{D1} represents a substituent and is preferably a substituent T described below. Among examples of R^{D1}, R^{D1} is preferably an alkyl group having 1 to 24 carbon atoms and more preferably an alkyl group having 1 to 12 carbon atoms.

nD represents an integer of 0 to 6 and is preferably an integer of 0 to 2 and particularly preferably 1.

Among these, it is preferable that X³—CO—X⁵ in the formula is NR^{N}—CO—CR^{C}₂, O—CO—O, or O—CO—CR^{C}₂.

Hereinafter, specific examples of the specific organic additive are described, but the present invention is not limited thereto.

TABLE A

| First group | | Second group | |
|---|---|---|---|
| Sulfolane | Sulfolane | AMTAZ | 2-amino-5-mercapto-1,3,4-thiadiazole |
| DMSO | Dimethyl sulfoxide | MTZ | 3-mercapto-1,2,4-triazole |
| XAN | Cyclohexanone | AMTZ | 3-amino-5-mercapto-1,2,4-triazole |
| MEK | Methyl ethyl ketone | DATZ | 3,5-diamino-1,2,4-triazole |
| DEGDM | Diethylene glycol dimethyl ether | MTAZ | 2-mercapto-1,3,4-thiadiazole |
| DEGDE | Diethylene glycol diethyl ether | DMTAZ | 2,5-dimercapto-1,3,4-thiadiazole |
| ACE | Ethyl acetate | TIU | Thiouracil |
| MPM | Methyl 3-methoxypropionate | ADE | Adenine |
| γ-BL | γ butyrolactone | MP | 6-methoxypurine |
| NMP | N-methylpyrrolidone | DAP | 2,6-diaminopurine |
| DMAA | NN-dimethylacetamide | Mpy | 2-mercaptopyridine |
| DIO | 1,4-dioxane | Hpy | 2-hydroxypyridine |
| EC | Ethylene carbonate | Apy | 2-aminopyridine |
| PC | Propylene carbonate | DAPy | 2,6-diaminopyridine |
| MSA | Methanesulfonic acid | DDT | 1-dodecanethiol |
| PPG | Polypropylene glycol having 3 to | DT | 1-decanethiol |
| | 100 carbon atoms | | |
| | | OT | 1-octanethiol |
| | | Cs | Cystine |
| | | CsT | Cysteine |
| | | ME | Mercaptoethanol |
| | | MPA | 3-mercaptopropionic acid |
| | | TS | Thiosalicylic acid |
| | | MBTz | 2-mercaptobenzothiazole |
| | | MBIz | 2-mercaptobenzoimidazole |
| | | MC | Mercaptosuccinic acid |
| | | DSA | Dodecylbenzenesulfonic acid |
| | | POEL | Polyoxyethylene lauryl ether sulfate |
| | | LSA | Lauryl sulfoacctate |
| | | ANSA | Alkyl naphthalene sulfonic acid |
| | | DBNA | Dibutyl naphthalene sulfonic acid |
| | | ADPNA | Alkyl diphenyl ether sulfonic acid |
| | | DDNA | Dodecyl naphthalene sulfonic acid |
| | | LPS | Lauryl phosphoric acid |
| | | LPz | Laurvl pyridinium chloride |
| | | LTMA | Lauryl trimethyl ammonium |
| | | LDMAB | Lauryl dimethyl aminoacetic acid betaine |
| | | LCHIB | 2-lauryl-N-carboxymethyl-N-hydroxyethylimidazolinium |
| | | | betaine |
| | | DMLAo | Dimethyl laurylamine oxide |
| | | DAPAc | 3-dodecylaminopropionic acid |

Alkyl groups of ANSA and ADPNA are respectively an isopropyl group and a dodecyl group.

The number of carbon atoms of polypropylene glycol is 6 to 100.

It is particularly preferable that the specific organic additive is formed of a compound listed in Table A of Example described below. Among the specific organic additives, the concentration of a specific organic additive belonging to the first group of Table A in the etching solution is preferably 50% by mass or greater, more preferably 55% by mass or greater, still more preferably 60% by mass or greater, and particularly preferably 70% by mass or greater. The upper limit thereof is preferably 99% by mass or less, more preferably 95% by mass or less, and particularly preferably 90% by mass or less.

Among the specific organic additives, the concentration of a specific organic additive belonging to the second group of Table A in the etching solution is preferably 0.005% by mass or greater, more preferably 0.01% by mass or greater, still more preferably 0.03% by mass or greater, and particularly preferably 0.05% by mass or greater. The upper limit thereof is preferably 10% by mass or less, more preferably 7% by mass or less, and particularly preferably 5% by mass or less.

It is preferable that the addition amount thereof is defined because damage of the germanium-containing layer (first layer) or the germanium silicide layer (third layer) can be effectively suppressed while excellent etching properties of the metal layer (second layer) are maintained.

The reason why the preferred ranges of the concentration of additives of the first group and the second group in Table A are different from each other is considered as follows from a difference of the action mechanism. That is, it is considered that the first group in Table A plays a role as a primary solvent in a treatment solution and acts on suppressing elution of components of the first layer containing germanium. Since the first group plays a role as a primary solvent and exhibits the effects, it is preferable that the concentration of the first group is high as described above. Meanwhile, an additive belonging to the second group in Table A is adsorbed on the surface of the first group containing germanium (Ge) and forms a protective layer on the surface thereof. Consequently, the amount of the additive of the second group to be added may be sufficient as long as the purpose of protecting the first layer is satisfied, and a relatively small amount thereof is preferable as described above.

In regard to the respective formulae described above and distinguishing the first group from the second group, it is preferable that compounds related to Formula (V) or part of Formula (V) and Formulae (VI), (IIX), (IX), and (XI) belong to the first group and compounds related to other formulae, Formula (V), or part of Formula (V) belong to the second group.

The definitions of the specific organic additive and the organic alkali compound overlap each other in some cases, but may be distinguished from each other from a viewpoint of functional aspects. That is, the organic alkali compound is mainly used as a component of accelerating etching and the specific organic additive is used as a component that plays a role of protecting a germanium layer. When the specific organic additive and the organic alkali compound are distinguished from each other, both can be distinguished by prioritizing the definition of the organic alkali compound and the specific organic additive is used for removing the compound.

Further, in the present invention, the specific organic additive may be used alone or in combination of two or more kinds thereof. The expression of the “combination of two or more kinds” includes not only a case in which a compound corresponding to Formula (I) and a compound corresponding to Formula (II) are combined to each other but also a case in which two compounds corresponding to Formula (I) are combined with each other (for example, two compounds in which at least one of atomic groups R¹¹, R¹², and X¹ is different from each other even though both of the compounds are represented by Formula (I)). In the case where two or more kinds are combined with each other, the combination ratio thereof is not particularly limited, but the total used amount thereof is preferably the above-described range of concentration as the sum of two or more kinds of specific organic additives.

The display of compounds in the present specification (for example, when a compound is referred to by being added at the end of the compound) is used to include the compound itself, a salt thereof, and an ion thereof. Further, the display thereof includes a derivative which is partially changed by being esterified or introducing a substituent within a range in which desired effects can be exhibited.

A substituent (the same applies to a linking group) in which substitution or unsubstitution is not specified in the present specification means that an arbitrary substituent may be included in the group. The same applies to a compound in which substitution or unsubstitution is not specified. As a preferred substituent, the substituent T described below is exemplified.

Examples of the substituent T include the followings.

An alkyl group (preferably an alkyl group having 1 to 20 carbon atoms such as methyl, ethyl, isopropyl, t-butyl, pentyl, heptyl, 1-ethylpentyl, benzyl, 2-ethoxyethyl, or 1-carboxymethyl), an alkenyl group (preferably, an alkenyl group having 2 to 20 carbon atoms such as vinyl, allyl, or oleyl), an alkynyl group (preferably an alkynyl group having 2 to 20 carbon atoms such as ethynyl, butadiynyl, or phenylethynyl), a cycloalkyl group (preferably a cycloalkyl group having 3 to 20 carbon atoms such as cyclopropyl, cyclopentyl, cyclohexyl, or 4-methylcyclohexyl), an aryl group (preferably an aryl group having 6 to 26 carbon atoms such as phenyl, 1-naphthyl, 4-methoxyphenyl, 2-chlorophenyl, or 3-methylphenyl), a heterocyclic group (preferably a heterocyclic group having 2 to 20 carbon atoms or preferably a heterocycle of a 5- or 6-membered ring having at least one of an oxygen atom, a sulfur atom and a nitrogen atom such as 2-pyridyl, 4-pyridyl, 2-imidazolyl, 2-benzimidazolyl, 2-thiazolyl, or 2-oxazolyl), an alkoxy group (preferably an alkoxy group having 1 to 20 carbon atoms such as methoxy, ethoxy, isopropyloxy, or benzyloxy), an aryloxy group (preferably an aryloxy group having 6 to 26 carbon atoms such as phenoxy, 1-naphthyloxy, 3-methylphenoxy, or 4-methoxyphenoxy), an alkoxycarbonyl group (preferably an alkoxycarbonyl group having 2 to 20 carbon atoms such as ethoxycarbonyl or 2-ethylhexyloxycarbonyl), an amino group (preferably an amino group having 0 to 20 carbon atoms, an alkylamino group having 0 to 20 carbon atoms, or an acylamino group having 0 to 20 carbon atoms such as amino, N,N-dimethylamino, N,N-diethylamino, N-ethylamino, or anilino), a sulfamoyl group (preferably a sulfonamide group having 0 to 20 carbon atoms such as N,N-dimethylsulfamoyl or N-phenylsulfamoyl), an acyl group (preferably an acyl group having 1 to 20 carbon atoms such as acetyl, propionyl, butyryl, or benzoyl), an acyloxy group (preferably an acyloxy group having 1 to 20 carbon atoms such as acetyloxy or benzoyloxy), a carbamoyl group (preferably a carbamoyl group having 1 to 20 carbon atoms such as N,N-dimethylcarbamoyl or N-phenylcarbamoyl), an acylamino group (preferably an acylamino group having 1 to 20 carbon atoms such as acetylamino or benzoylamino), a sulfonamide group (preferably a sulfamoyl group having 0 to 20 carbon atoms such as methanesulfonamide, benzenesulfonamide, N-methylmethanesulfonamide, or N-ethylbenzenesulfonamide), an alkylthio group (preferably an alkylthio group having 1 to 20 carbon atoms such as methylthio, ethylthio, isopropylthio, or benzylthio), an arylthio group (preferably an arylthio group having 6 to 26 carbon atoms such as phenylthio, 1-naphthylthio, 3-methylphenylthio, or 4-methoxyphenylthio), alkyl or an arylsulfonyl group (preferably alkyl or an arylsulfonyl group having 1 to 20 carbon atoms such as methylsulfonyl, ethylsulfonyl, or benzenesulfonyl), and a hydroxyl group, a sulfanyl group, a cyano group, and a halogen atom (such as a fluorine atom, a chlorine atom, a bromine atom, or an iodine atom). Among these, an alkyl group, an alkenyl group, an aryl group, a heterocyclic group, an alkoxy group, an aryloxy group, an alkoxycarbonyl group, an amino group, an acylamino group, a hydroxyl group or a halogen atom is more preferable. Further, an alkyl group, an alkenyl group, a heterocyclic group, an alkoxy group, an alkoxycarbonyl group, an amino group, an acylamino group, or a hydroxyl group is particularly preferable.

Moreover, respective groups exemplified in these substituents T may be further substituted with the above-described substituents T.

When a compound or a substituent and a linking group include an alkyl group/an alkylene group, an alkenyl group/an alkenylene group, or an alkynyl group/an alkynylene group, these may be cyclic, chain-like, linear, or branched and may be substituted or unsubstituted as described above. Moreover, when an aryl group and a heterocyclic group are included, these may be a single ring or a condensed ring and may be substituted or unsubstituted.

(Aqueous Medium)

In the present invention, water (aqueous medium) may be used as a medium of the etching solution. An aqueous medium containing dissolved components within a range not damaging the effects of the present invention may be used as water (aqueous medium) or water may contain a small amount of inevitable mixing components. Among these, water subjected to a purification treatment such as distilled water, ion-exchange water, or ultrapure water is preferable and ultrapure water to be used for manufacturing a semiconductor is particularly preferable.

(Kit)

The etching solution in the present invention may be used for a kit obtained by dividing the raw material of the etching solution into plural parts. For example, an aspect in which a liquid composition containing the above-described organic alkali compound in water as a first liquid is prepared and a liquid composition containing the above-described oxidant in an aqueous medium as a second liquid is prepared is exemplified. At this time, the components of another organic additive and the like can be separately contained or can be contained together in a first liquid, a second liquid, or another third liquid. The preferable aspect is to prepare a kit of the first liquid containing an organic alkali compound and a specific organic compound and the second liquid containing an oxidant.

As the usage example, an aspect of preparing an etching solution by mixing both of the liquids and then using the etching solution for the etching treatment at a suitable time is preferable. In this manner, deterioration of liquid performance due to decomposition of respective components is not caused and a desired etching action can be effectively exhibited. Here, the term “suitable time” after mixing both of the liquids indicates a period during which a desired action is lost after the mixing, and, specifically, the period is preferably within 60 minutes, more preferably within 30 minutes, still more preferably within 10 minutes, and particularly preferably within 1 minute. The lower limit thereof, which is not particularly limited, is substantively 1 second or longer.

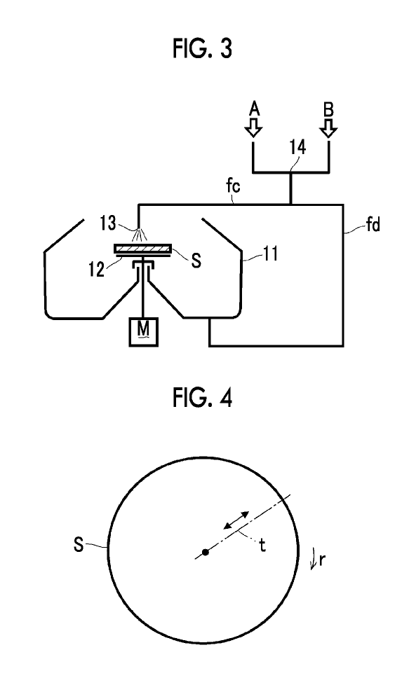

The manner of mixing the first liquid and the second liquid is not particularly limited, but the mixing is preferably performed by circulating the first liquid and the second liquid in different channels and merging both of the liquids at a junction point. Subsequently, both of the liquids are circulated through the channels, an etching solution obtained after both of the liquids are merged is ejected or sprayed from an ejection opening, and the etching solution is brought into contact with a semiconductor substrate. In the embodiment, it is preferable that the process from which both of the liquids are merged and mixed with each other at the junction point to which the solution is brought into contact with the semiconductor substrate is performed at the “suitable time” described above. When this process is described with reference to FIG. 3, the prepared etching solution is sprayed from an ejection opening 13 and then applied to the upper surface of a semiconductor substrate S in a treatment container (treatment tank) 11. In the embodiment shown in the same figure, two liquids of A and B are supplied to be merged with each other at a junction point 14 and then the liquids are transitioned to the ejection opening 13 through a channel fc. A channel fd indicates a returning path for reusing a liquid chemical. It is preferable that the semiconductor substrate S is on a rotary table 12 and rotates along with the rotary table by a rotation driving unit M. In addition, in the embodiment in which such a substrate rotation type device is used, the same applies to a treatment using the etching solution which is not used for a kit.

Moreover, in the etching solution of the present invention, it is preferable that the amount of impurities in the solution, for example, metal is small when the usage of the etching solution is considered. Particularly, the ion concentration of Na, K, and Ca in the solution is preferably in the range of 1 ppt to 1 ppm. Further, in the etching solution, the number of coarse particles having an average particle diameter of 0.5 μm or greater is preferably 100/cm³ or less and more preferably 50/cm³ or less.

(Container)

The etching liquid of the present invention fills an arbitrary container to be stored, transported, and then used as long as corrosion resistance is not a problem (regardless of the container being a kit or not). Further, a container whose cleanliness is high and in which the amount of impurities to be eluted is small is preferable for the purpose of using the container for a semiconductor. As a usable container, “Clean bottle” series (manufactured by ACELLO CORPORATION) or “Pure bottle” (manufactured by KODAMA PLASTICS Co., Ltd.) is exemplified, but the examples are not limited thereto.

[Etching Conditions]

In an etching method of the present invention, it is preferable to use a sheet type device. Specifically, a sheet type device which has a treatment tank and in which the semiconductor substrate is transported or rotated in the treatment tank, the etching solution is provided (ejection, spray, falling, dropping, or the like) in the treatment tank, and the etching solution is brought into contact with the semiconductor substrate is preferable.

Advantages of the sheet type device are as follows: (i) a fresh etching solution is constantly supplied and thus reproducibility is excellent and (ii) in-plane uniformity is high. Further, a kit obtained by dividing the etching solution into plural parts is easily used and, for example, a method of mixing the first and second liquids with each other in line and ejecting the liquid is suitably employed. At this time, a method of mixing the liquids with each other in line and ejecting the mixed solution after the temperature of both of the first liquid and the second liquid is adjusted or the temperature of one of the first liquid and the second liquid is adjusted is preferable. Between the two, adjusting the temperature of both liquids is more preferable. It is preferable that the managed temperature at the time of adjusting the temperature of the line is set to be in the same range as that of the treatment temperature described below.

The sheet type device is preferably provided with a nozzle in the treatment tank thereof and a method of ejecting the etching solution to the semiconductor substrate by swinging the nozzle in the plane direction of the semiconductor substrate is preferable. In this manner, deterioration of the solution can be prevented, which is preferable. Further, the solution is separated into two or more liquids after the kit is prepared and thus gas or the like is unlikely to be generated, which is preferable.

The treatment temperature of performing etching in the method of measuring the temperature in Example below is preferably 30° C. or higher and more preferably 40° C. or higher. The upper limit thereof is preferably 80° C. or lower, more preferably 70° C. or lower, and still more preferably 60° C. or lower. It is preferable that the temperature is set to be higher than or equal to the lower limit because the etching rate with respect to the second layer can be sufficiently secured. It is preferable that the temperature thereof is set to be lower than or equal to the upper limit thereof because stability over time for the rate of the etching treatment can be maintained.

The rate of supplying the etching solution, which is not particularly limited, is preferably in the range of 0.05 L/min to 5 L/min and more preferably in the range of 0.1 L/min to 3 L/min. It is preferable that the rate thereof is set to be greater than or equal to the lower limit because the in-plane uniformity of etching can be more excellently secured. It is preferable that the rate thereof is set to be less than or equal to the upper limit because the performance stabilized at the time of performing a treatment continuously can be secured. The rotation of the semiconductor substrate also depends on the size thereof and the semiconductor substrate rotates preferably at 50 rpm to 1000 rpm from the same viewpoint described above.

In sheet type etching according to the preferred embodiment of the present invention, it is preferable that the semiconductor substrate is transported or rotated in a predetermined direction and an etching solution is brought into contact with the semiconductor substrate by spraying the etching solution to the space of the semiconductor substrate. The rate of supplying the etching solution and the rotation rate of the substrate are the same as those described above.

In the configuration of the sheet type device according to the preferred embodiment of the present invention, it is preferable that the etching solution is provided while the ejection opening (nozzle) is moved as illustrated in FIG. 4. Specifically, in the present embodiment, the substrate is rotated in an r direction when the etching solution is applied to the semiconductor substrate S. Further, the ejection opening is set to move along a movement locus line t extending to the end portion from the central portion of the semiconductor substrate. In this manner, the rotation direction of the substrate and the movement direction of the ejection opening are set to be different from each other in the present embodiment and thus both directions are set to be relatively moved. As a result, the etching solution can be evenly provided for the entire surface of the semiconductor substrate and the uniformity of etching is suitably secured.

The moving speed of the ejection opening (nozzle), which is not particularly limited, is preferably 0.1 cm/s or greater and more preferably 1 cm/s or greater. The upper limit thereof is preferably 30 cm/s or less and more preferably 15 cm/s or less. The movement locus line may be linear or curved (for example, ark-shaped). In both cases, the movement speed can be calculated from the distance of an actual locus line and the time spent for the movement thereof. The time required for etching one sheet of substrate is preferably in the range of 10 seconds to 180 seconds.

It is preferable that the metal layer is etched at a high etching rate. An etching rate [R2] of the second layer (metal layer) varies depending on the kind of metal, but is preferably 0.1 Å/min or greater, more preferably 1 Å/min or greater, and particularly preferably 5 Å/min or greater in terms of productivity. The upper limit, which is not particularly limited, is substantively 1200 Å/min or less.

The exposure width of the metal layer, which is not particularly limited, is preferably 2 nm or greater and more preferably 4 nm or greater from a viewpoint that the advantages of the present invention become remarkable. The upper limit thereof is substantively 1000 nm or less, preferably 100 nm or less, and more preferably 20 nm or less from a viewpoint that the effects thereof become significant in the same manner.

An etching rate [R1] of the layer (first layer) containing germanium or the germanium silicide layer (third layer) is not particularly limited, and it is preferable that the layer is not excessively removed. The etching rate thereof is preferably 50 Å/min or less, more preferably 20 Å/min or less, and particularly preferably 10 Å/min or less. The lower limit thereof, which is not particularly limited, is substantively 0.1 Å/min or greater when the measurement limit is considered.

In the selective etching of the first layer, the ratio of the etching rate ([R2]/[R1]), which is not particularly limited, is preferably 2 or greater, more preferably 10 or greater, and still more preferably 20 or greater from a viewpoint of elements which need high selectivity. The upper limit thereof, which is not particularly limited, is preferred as the value becomes larger, but the upper limit thereof is substantively 5000 or less. Further, the etching behavior of the germanium silicide layer (third layer) is in common with a layer before annealing (for example, the first layer of SiGe or Ge) and thus the germanium silicide layer can be substituted with the layer before annealing is applied thereto according to the etching rate of the first layer.

[Manufacture of Semiconductor Substrate Product]

In the present embodiment, it is preferable that a semiconductor substrate product having a desired structure is manufactured through a process of preparing a semiconductor substrate on which the silicon layer and the metal layer are formed on a silicon wafer, a process of annealing the semiconductor substrate, and a process of providing the etching solution for the semiconductor substrate such that the etching solution is brought into contact with the metal layer and selectively removing the metal layer. At this time, the specific etching solution is used for etching. The order of the processes is not limited and other processes may be further included between respective processes.

The size of a wafer is not particularly limited, but a wafer whose diameter is 8 inches, 12 inches, or 14 inches is preferably used.

### Examples

Hereinafter, the present invention will be specifically described with reference to Examples, but the present invention is not limited to Examples described below.

(Preparation of Evaluation Substrate)

SiGe was epitaxially grown to be formed to have a film thickness of 50 nm on a commercially available silicon substrate (diameter: 12 inches). At this time, the SiGe epitaxial layer contained 50% by mass to 60% by mass of germanium. In the same manner, blanket wafers created by CVD or the like were prepared for a NiPt film (thickness: 20 nm, ratio of Pt/Ni:10/90 [on a mass basis]). The test of the etching treatment below was performed using these blanket wafers.

(Etching Test)

SWT

The etching was performed under the following conditions with a sheet type device (POLOS (trade name), manufactured by SPS-Europe B. V.) with respect to the substrate for a test and an evaluation test was carried out.
Treatment temperature: 50° C.
Ejection amount: 1 L/min
Wafer rotation speed: 500 rpm
Nozzle movement speed: 7 cm/sec

Further, the etching solution was supplied by being divided into two liquids as described below to be line mixed (see FIG. 3). A supply line fc was heated such that the temperature thereof was adjusted to 60° C.

First liquid (A): alkali compound and water as needed

Second liquid (B): oxidant and water as needed

The ejection amount of the first liquid and the second liquid was adjusted and treated such that the organic alkali and the oxidant have the ratios listed in Table 1. According to the formulation, when an alkali compound was singly used, a treatment using only one liquid was carried out in this case. It did not take much time from the mixture of two liquids to provision of the mixed solution for the substrate and this means that the mixed solution was provided for the substrate immediately after the mixing.

(Method of Measuring Treatment Temperature)

A radiation thermometer IT-550F (trade name, manufactured by HORIBA, Ltd.) was fixed to a position having a height of 30 cm on a wafer in the sheet type device. The thermometer was directed to the surface of the wafer outside from the center thereof by a distance of 2 cm and the temperature was measured while circulating a liquid chemical. The temperature was continuously recorded using a computer through digital output from the radiation thermometer. Among these, a value obtained by averaging the recorded values of the temperature for 10 seconds at the time when the temperature thereof was stabilized was set as a temperature on the wafer.

(Etching Rate)

The etching rate (ER) was calculated by measuring the film thickness before or after the etching treatment using Ellipsometry (VASE Spectroscopic ellipsometer was used, J. A. Woollam, Japan). The average value of five points was adopted (measurement condition: measurement range: 1.2 eV to 2.5 eV, measuring angles: 70 degrees and 75 degrees).

TABLE 1

| Test | | % by | | % by | | NiPt ER | SiGc ER |
|---|---|---|---|---|---|---|---|
| No. | Organic alkali | mass | Oxidant | mass | Remainder | Å/min | Å/min |
| 101 | Ethylenediamine | 100 | — | — | — | 16 | 19 |
| 102 | Ethylamine | 100 | — | — | — | 14 | 17 |
| 103 | 1,3-propanediamine | 100 | — | — | — | 24 | 12 |
| 104 | 1,4-butanediamine | 100 | — | — | — | 23 | 12 |
| 105 | N,N-dimethylethylenediamine | 100 | — | — | — | 24 | 16 |
| 106 | n-pentylamine | 100 | — | — | — | 21 | 4 |
| 107 | Benzylamine | 100 | — | — | — | 16 | 3 |
| 108 | Cyclohexylamine | 100 | — | — | — | 21 | 5 |
| 109 | n-hexylamine | 100 | — | — | — | 19 | 1 |
| 110 | n-octylamine | 100 | — | — | — | 18 | 2 |
| 111 | 2-ethylhexylamine | 100 | — | — | — | 18 | 0 |
| 112 | m-xylylenediamine | 100 | — | — | — | 14 | 6 |
| 113 | Monoethanolamine | 100 | — | — | — | 20 | 2 |
| 114 | N,N-diethylethanolamine | 100 | — | — | — | 16 | 1 |
| 115 | Diethanolamine | 100 | — | — | — | 20 | 3 |
| 116 | Diglycolamine | 100 | — | — | — | 16 | 5 |
| 117 | Triethanolamine | 100 | — | — | — | 18 | 1 |
| 118 | N-methylethanolamine | 100 | — | — | — | 17 | 2 |
| 119 | N-methylhydroxylamine | 100 | — | — | — | 21 | 3 |
| 120 | Isopropanolamine | 100 | — | — | — | 21 | 5 |
| 121 | N,N-diisopropanolamine | 100 | — | — | — | 19 | 4 |
| 122 | 2-(methylamino)ethanol | 100 | — | — | — | 22 | 6 |
| 123 | 3-ethoxypropylamine | 100 | — | — | — | 24 | 5 |
| 124 | Methyl carbazic acid | 30 | — | — | Water | 18 | 2 |
| 125 | O-methylhydroxylamine | 30 | — | — | Water | 12 | 2 |
| 126 | Tetramethylammonium hydroxide | 20 | — | — | Water | 24 | 16 |
| 127 | Tetraethylammonium hydroxide | 20 | — | — | Water | 23 | 1 |
| 128 | Tetra n-propylammonium hydroxide | 10 | — | — | Water | 24 | 1 |
| 129 | Tetraisopropylammonium hydroxide | 10 | — | — | Water | 30 | 2 |
| 130 | Tetra n-butylammonium hydroxide | 10 | — | — | Water | 25 | 1 |
| 131 | Tetra t-butylammonium hydroxide | 10 | — | — | Water | 25 | 1 |
| 132 | Choline hydroxide | 25 | — | — | Water | 23 | 3 |
| 201 | Ethylenediamine | 60 | Hydrogen peroxide | 10 | Water | 35 | 21 |
| 202 | 1,3-propanediamine | 60 | Hydrogen peroxide | 10 | Water | 34 | 15 |
| 203 | n-pentylamine | 60 | Hydrogen peroxide | 10 | Water | 36 | 1 |
| 204 | Benzylamine | 60 | Hydrogen peroxide | 10 | Water | 38 | 3 |
| 205 | n-hexylamine | 60 | Hydrogen peroxide | 10 | Water | 42 | 2 |
| 206 | 2-ethylhexylamine | 60 | Hydrogen peroxide | 10 | Water | 41 | 3 |
| 207 | Monoethanolamine | 60 | Hydrogen peroxide | 10 | Water | 38 | 5 |
| 208 | Diethanolamine | 60 | Hydrogen peroxide | 10 | Water | 39 | 6 |
| 209 | Tetramethylammonium hydroxide | 15 | Hydrogen peroxide | 10 | Water | 45 | 30 |
| 210 | Tetraethylammonium hydroxide | 15 | Hydrogen peroxide | 10 | Water | 51 | 3 |
| 211 | Tetra n-propylammonium hydroxide | 8 | Hydrogen peroxide | 10 | Water | 51 | 2 |
| 212 | Tetra n-butylammonium hydroxide | 8 | Hydrogen peroxide | 10 | Water | 50 | 1 |
| C01 | — | — | — | — | Water | 0 | 0 |
| C02 | — | — | Hydrogen peroxide | 10 | Water | 0 | 10 |
| C03 | — | — | — | — | Isopropanol | 0 | 5 |

ER: etching rate

According to the present invention, it is understood that the second layer containing a specific metal can be selectively removed with respect to the layer containing germanium. In a hydrocarbon amine compound or an ammonium compound having a large number of carbon atoms and a hydrocarbon amine compound or an ammonium compound having an oxygen atom, it is understood that the etching rate of SiGe is suppressed and thus the etching selectivity of the metal layer is improved.

Further, when evaluation is performed on a substrate having a SiGe layer, a NiPt metal layer, and a germanium silicide layer formed by the annealing treatment between the SiGe layer and the NiPt metal layer in place of the above-described substrate, it is confirmed that selective etching performance is exhibited with respect to NiPt.

Tests were performed in the same manner as in the above-described tests 101 to 212 except that 1.0% by mass of the above-described exemplary compounds A-1 to A-18 was added. As a result, excellent etching properties were shown with respect to NiPt (10 Å/min or greater), but the etching rate with respect to the SiGe layer was reduced by half.

### EXPLANATION OF REFERENCES

1: metal layer (second layer)
2: germanium layer (first layer)
3: germanium silicide layer (third layer)
11: treatment container (treatment tank)
12: rotary table
13: ejection opening
14: junction point
S: substrate
21: silicon substrate
22: gate insulating film
23: gate electrode
25: side wall
26: source electrode
27: drain electrode
28: NiPt film
90A, 90B: replacement gate stack
92A, 92B: well
94A, 94B: source/drain extension region
96A, 96B: source/drain region
91A, 91B: metal semiconductor alloy portion
95A, 95B: gate spacer
97A, 97B: gate insulting film
81: first work function material layer
82A, 82B: second work function material layer
83A, 83B: metal portion
93: trench structure portion
99: flattened dielectric layer

The present invention has been described with reference to the embodiments, but the detailed description of the invention is not intended to limit the invention unless otherwise noted and the present invention should be broadly interpreted without departing from the spirit and the scope described in the aspects of the invention.

What is claimed is:

1. An etching solution of a semiconductor substrate that includes a first layer containing germanium (Ge) and a second layer containing a specific metal element other than germanium (Ge), the etching solution selectively removing the second layer and comprising an organic alkali compound.

2. The etching solution according to claim 1, wherein the organic alkali compound is (a) a hydrocarbon amine compound having 3 or more carbon atoms, (b) an amine compound containing an oxygen atom or a sulfur atom, or (c) an ammonium compound having 5 or more carbon atoms or an ammonium compound having an oxygen atom or a sulfur atom.

3. The etching solution according to claim 1, wherein the concentration of germanium (Ge) of the first layer is 40% by mass or greater.

4. The etching solution according to claim 1, wherein the specific metal element constituting the second layer is selected from nickel platinum (NiPt), titanium (Ti), nickel (Ni), and cobalt (Co).

5. The etching solution according to claim 1, wherein the organic alkali compound is a compound represented by any of the following Formulae (O-1) to (O-3), (P-1) to (P-3), and (Q-1), a compound having a repeating unit selected from the following Formulae (a-1) to (a-8), or a compound represented by the following Formula (b), 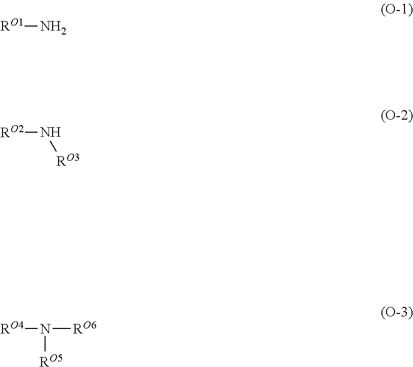
in the formulae, R⁰¹ each independently represents an alkyl group (having 3 to 12 carbon atoms), an alkenyl group (having 1 to 12 carbon atoms), an alkynyl group (having 1 to 12 carbon atoms), or an aryl group (having 6 to 14 carbon atoms), R⁰² to R⁰⁶ each independently represent an alkyl group (having 1 to 12 carbon atoms), an alkenyl group (having 1 to 12 carbon atoms), an alkynyl group (having 1 to 12 carbon atoms), or an aryl group (having 6 to 14 carbon atoms), in this case, the alkyl group, the alkenyl group, the alkynyl group, or the aryl group herein may further include an amino group, but do not include a substituent having an oxygen atom or a sulfur atom, 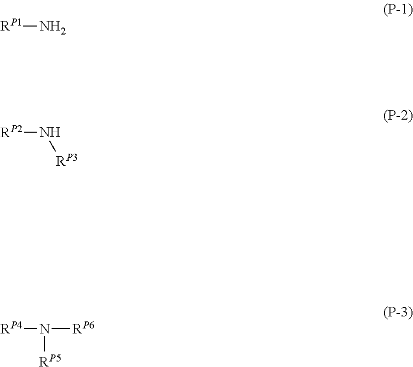
in the formulae, R^{P1} to R^{P6} each independently represent an acyl group (having 1 to 6 carbon atoms), an alkoxy group (having 1 to 6 carbon atoms), an alkoxycarbonyl group (having 2 to 6 carbon atoms), an alkoxycarbonylamino group (having 2 to 6 carbon atoms), a group represented by the following Formula (x), an alkyl group (having 1 to 6 carbon atoms), an alkenyl group (having 2 to 6 carbon atoms), an alkynyl group (having 2 to 6 carbon atoms), an aryl group (having 6 to 10 carbon atoms), or a heterocyclic group (having 2 to 6 carbon atoms), in this case, R^{P}1 in Formula (P-1) does not represent a hydrocarbon group, both of R^{P2} and R^{P3} in Formula (P-2) do not only represent a hydrocarbon group, in Formula (P-3), all of R^{P4} to R^{P6} do not only represent a hydrocarbon group,
X1-(Rx1-X2)mx-Rx2-* (X)
X1 represents a hydroxy group, a sulfanyl group, an alkoxy group having 1 to 4 carbon atoms, or a thioalkoxy group having 1 to 4 carbon atoms, Rx1 and Rx2 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these, X2 represents O, S, CO, NR^{N} (R^{N} represents a hydrogen atom or an alkyl group having 1 to 6 carbon atoms), mx represents an integer of 0 to 6, when mx is 2 or greater, a plurality of Rx1's and X2's may be different from each other, Rx1 and Rx2 may further include a substituent T, the symbol “*” indicates an atomic bond, 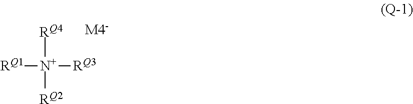
in the formula, R^{Q1} to R^{Q4} each independently represent an alkyl group having 1 to 20 carbon atoms, an alkenyl group having 2 to 20 carbon atoms, an alkynyl group having 2 to 20 carbon atoms, an aryl group having 6 to 14 carbon atoms, an aralkyl group having 7 to 14 carbon atoms, or a group represented by the following Formula (y), in this case, when the total number of carbon atoms of R^{Q1} to R^{Q4} is 5 or more or the total number of carbon atoms of R^{Q1} to R^{Q4} is 4, any one of R^{Q1} to R^{Q4} includes a substituent having an oxygen atom or a sulfur atom,
Y1-(Ry1-Y2)my-Ry2-* (y)
Y1 represents an alkyl group having 1 to 12 carbon atoms, an alkenyl group having 2 to 12 carbon atoms, an alkynyl group having 2 to 12 carbon atoms, an aralkyl group having 7 to 14 carbon atoms, an aryl group having 6 to 14 carbon atoms, a hydroxy group, a sulfanyl group, an alkoxy group having 1 to 4 carbon atoms, or a thioalkoxy group having 1 to 4 carbon atoms, Y2 represents O, S, CO, or NR^{N} (R^{N} represents a hydrogen atom or an alkyl group having 1 to 6 carbon atoms), Ry1 and Ry2 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these, my represents an integer of 0 to 6, when my is 2 or greater, a plurality of Ry1's and Y2's may be different from each other, Ry1 and Ry2 may further include a substituent T, the symbol “*” indicates an atomic bond,
M4⁻ represents a counterion, 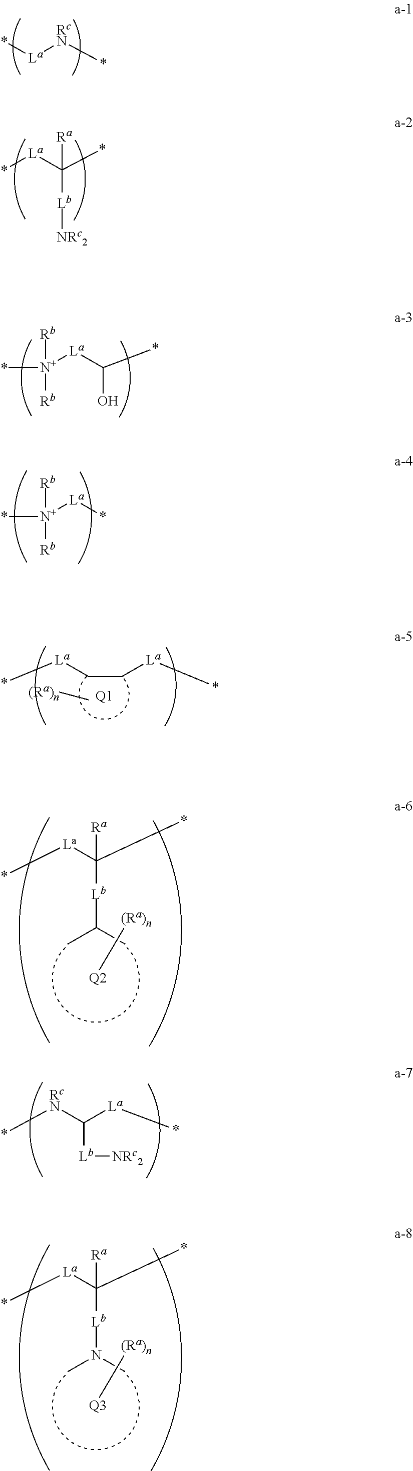
R^{a} represents a hydrogen atom, an alkyl group, an alkenyl group, an aryl group, or a heterocyclic group, R^{b} represents an alkyl group or an alkenyl group, L^{a} represents an alkylene group, a carbonyl group, an imino group, an arylene group, a heterocyclic group, or a combination of these, among these, an alkylene group or a carbonyl group is preferable, L^{b} represents a single bond, an alkylene group, a carbonyl group, an imino group, an arylene group, a heterocyclic group, or a combination of these, R^{c} represents a hydrogen atom or an alkyl group, n represents an integer of 0 or greater, Q1 to Q3 each independently represent a nitrogen-containing heterocycle,
R^{c}₂N-[L^{d}-N(R^{c})]ₘ-L^{d}-NR^{c}₂ (b)
R^{c} represents a hydrogen atom or an alkyl group, m represents an integer of 0 or greater, L^{d} represents an alkylene group, a carbonyl group, an imino group, an arylene group, a heterocyclic group, or a combination of these.

6. The etching solution according to claim 1, wherein the organic alkali compound is selected from a group consisting of an alkylamine compound having 3 or more carbon atoms, an alkylammonium compound having 5 or more carbon atoms, a carbamoyl compound, and an alkoxyamine compound.

7. The etching solution according to claim 1, wherein the content of the organic alkali compound is in the range of 3% by mass to 100% by mass.

8. The etching solution according to claim 1, wherein the second layer is selectively removed with respect to the first layer and the following third layer.
Third layer: layer containing germanium (Ge) and the specific metal element, which is interposed between the first layer and the second layer.

9. The etching solution according to claim 1, further comprising the following organic additive.
Organic additive: an additive formed of an organic compound which contains a nitrogen atom, a sulfur atom, a phosphorous atom, or an oxygen atom

10. An etching solution kit of a semiconductor substrate that includes a first layer containing germanium (Ge) and a second layer containing a metal element, the kit selectively removing the second layer and comprising:
a first liquid which contains an organic alkali compound; and
a second liquid which contains an oxidant.

11. An etching method of a semiconductor substrate that includes a first layer containing germanium (Ge) and a second layer containing a specific metal element other than germanium (Ge), the method comprising:
selectively removing the second layer; and
using an etching solution containing an organic alkali compound.

12. The etching method according to claim 11, wherein the organic alkali compound is (a) a hydrocarbon amine compound having 5 or more carbon atoms, (b) an amine compound containing a heteroatom, or (c) an ammonium compound.

13. The etching method according to claim 11, wherein the concentration of germanium (Ge) of the first layer is 40% by mass or greater.

14. The etching method according to claim 11, wherein the specific metal element constituting the second layer is selected from nickel platinum (NiPt), titanium (Ti), nickel (Ni), and cobalt (Co).

15. The etching method according to claim 11, wherein the organic alkali compound is a compound represented by any of the following Formulae (O-1) to (O-3), (P-1) to (P-3), and (Q-1), a compound having a repeating unit selected from the following Formulae (a-1) to (a-8), or a compound represented by the following Formula (b), 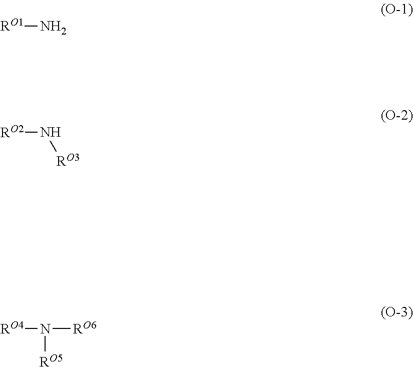
in the formulae, R⁰¹ each independently represents an alkyl group (having 3 to 12 carbon atoms), an alkenyl group (having 1 to 12 carbon atoms), an alkynyl group (having 1 to 12 carbon atoms), or an aryl group (having 6 to 14 carbon atoms), R⁰² to R⁰⁶ each independently represent an alkyl group (having 1 to 12 carbon atoms), an alkenyl group (having 1 to 12 carbon atoms), an alkynyl group (having 1 to 12 carbon atoms), or an aryl group (having 6 to 14 carbon atoms), in this case, the alkyl group, the alkenyl group, the alkynyl group, or the aryl group herein may further include an amino group, but do not include a substituent having an oxygen atom or a sulfur atom, 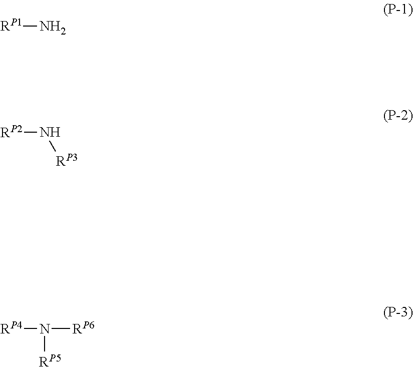
in the formulae, R^{P1} to R^{P6} each independently represent an acyl group (having 1 to 6 carbon atoms), an alkoxy group (having 1 to 6 carbon atoms), an alkoxycarbonyl group (having 2 to 6 carbon atoms), an alkoxycarbonylamino group (having 2 to 6 carbon atoms), a group represented by the following Formula (x), an alkyl group (having 1 to 6 carbon atoms), an alkenyl group (having 2 to 6 carbon atoms), an alkynyl group (having 2 to 6 carbon atoms), an aryl group (having 6 to 10 carbon atoms), or a heterocyclic group (having 2 to 6 carbon atoms), in this case, R^{P1} in Formula (P-1) does not represent a hydrocarbon group, both of R^{P2} and R^{P3} in Formula (P-2) do not only represent a hydrocarbon group, in Formula (P-3), all of R^{P4} to R^{P6} do not only represent a hydrocarbon group,
X1-(Rx1-X2)mx-Rx2-* (X)
X1 represents a hydroxy group, a sulfanyl group, an alkoxy group having 1 to 4 carbon atoms, or a thioalkoxy group having 1 to 4 carbon atoms, Rx1 and Rx2 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these, X2 represents O, S, CO, NR^{N} (R^{N} represents a hydrogen atom or an alkyl group having 1 to 6 carbon atoms), mx represents an integer of 0 to 6, when mx is 2 or greater, a plurality of Rx1 's and X2's may be different from each other, Rx1 and Rx2 may further include a substituent T, the symbol “*” indicates an atomic bond, 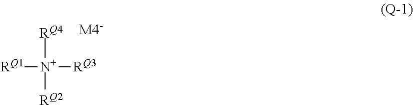
in the formula, R^{Q1} to R^{Q4} each independently represent an alkyl group having 1 to 20 carbon atoms, an alkenyl group having 2 to 20 carbon atoms, an alkynyl group having 2 to 20 carbon atoms, an aryl group having 6 to 14 carbon atoms, an aralkyl group having 7 to 14 carbon atoms, or a group represented by the following Formula (y), in this case, when the total number of carbon atoms of R^{Q1} to R^{Q4} is 5 or more or the total number of carbon atoms of R^{Q1} to R^{Q4} is 4, any one of R^{Q1} to R^{Q4} includes a substituent having an oxygen atom or a sulfur atom,
Y1-(Ry1-Y2)my-Ry2-* (y)
Y1 represents an alkyl group having 1 to 12 carbon atoms, an alkenyl group having 2 to 12 carbon atoms, an alkynyl group having 2 to 12 carbon atoms, an aralkyl group having 7 to 14 carbon atoms, an aryl group having 6 to 14 carbon atoms, a hydroxy group, a sulfanyl group, an alkoxy group having 1 to 4 carbon atoms, or a thioalkoxy group having 1 to 4 carbon atoms, Y2 represents O, S, CO, or NR^{N} (R^{N} represents a hydrogen atom or an alkyl group having 1 to 6 carbon atoms), Ry1 and Ry2 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these, my represents an integer of 0 to 6, when my is 2 or greater, a plurality of Ry1's and Y2's may be different from each other, Ry1 and Ry2 may further include a substituent T, the symbol “*” indicates an atomic bond,
M4⁻ represents a counterion, 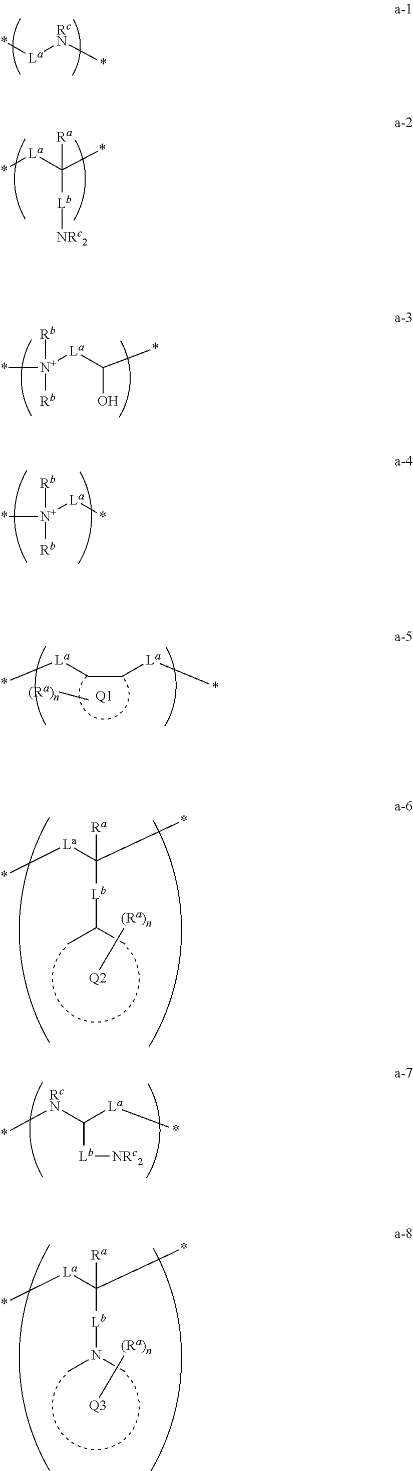
R^{a} represents a hydrogen atom, an alkyl group, an alkenyl group, an aryl group, or a heterocyclic group, R^{b} represents an alkyl group or an alkenyl group, L^{a} represents an alkylene group, a carbonyl group, an imino group, an arylene group, a heterocyclic group, or a combination of these, among these, an alkylene group or a carbonyl group is preferable, L^{b} represents a single bond, an alkylene group, a carbonyl group, an imino group, an arylene group, a heterocyclic group, or a combination of these, R^{c} represents a hydrogen atom or an alkyl group, n represents an integer of 0 or greater, Q1 to Q3 each independently represent a nitrogen-containing heterocycle,
R^{c}₂N-[L^{d}-N(R^{c})]ₘ-L^{d}-NR^{c}₂ (b)
R^{c} represents a hydrogen atom or an alkyl group, m represents an integer of 0 or greater, L^{d} represents an alkylene group, a carbonyl group, an imino group, an arylene group, a heterocyclic group, or a combination of these.

16. The etching method according to claim 11, wherein the content of the organic alkali compound is in the range of 3% by mass to 100% by mass.

17. The etching method according to claim 11, wherein the second layer is selectively removed with respect to the first layer and the following third layer.
Third layer: layer containing germanium (Ge) and the specific metal element, which is interposed between the first layer and the second layer

18. The etching method according to claim 11, further comprising:
allowing the semiconductor substrate to rotate and supplying the etching solution through a nozzle from the upper surface of the semiconductor substrate during rotation when the etching solution is provided for the semiconductor substrate.

19. The etching method according to claim 11, wherein the temperature of the etching solution at the time of being brought into contact with the second layer is in the range of 30° C. to 80° C.

20. The etching method according to claim 11, further comprising:
a step of washing the semiconductor substrate with water at least before or after the etching.

21. The etching method according to claim 11,
wherein the etching solution further contains an oxidant, and
a first liquid which does not contain the oxidant and a second liquid which contains the oxidant are separated from each other and then stored.

22. A method for manufacturing a semiconductor substrate product that includes a first layer containing germanium (Ge), comprising:
a step of forming at least the first layer and at least one second layer selected from nickel platinum (NiPt), titanium (Ti), nickel (Ni), and cobalt (Co) on the semiconductor substrate;
a step of forming a third layer containing components of the first layer and the second layer between both layers by heating the semiconductor substrate;
a step of preparing an etching solution containing an organic alkali compound; and
a step of bringing the etching solution into contact with the second layer and selectively removing the second layer with respect to the first layer and/or the third layer.
